(19) United States
(12) Patent Application Publication
(10) Pub. No.: US 2025/0351743 A1
(43) Pub. Date: Nov. 13, 2025

(54) TECHNOLOGIES FOR SCALABLE SPIN QUBIT ARRAYS

(71) Applicant: Intel Corporation, Santa Clara, CA (US)

(72) Inventors: Hubert C. George, Highlands Ranch, CO (US); Ravi Pillarisetty, Portland, OR (US); Fahd Ayyalil Mohiyaddin, Beaverton, OR (US); Roza Kotlyar, Camas, WA (US); Mohammad Islam, Portland, OR (US); Eric Michael Henry, Forest Grove, OR (US); Stephanie Bojarski, Beaverton, OR (US); Bishnu Prasad Patra, Hillsboro, OR (US); Thomas F. Watson, Portland, OR (US); Guoji Zheng, The Hague (NL); Matthew Jon Curry, Beaverton, OR (US); Samuel Neyens, Portland, OR (US); Florian Luethi, Portland, OR (US); Lester F. Lampert, Portland, OR (US); James S. Clarke, Portland, OR (US)

(73) Assignee: Intel Corporation, Santa Clara, CA (US)

(21) Appl. No.: 19/080,656

(22) Filed: Mar. 14, 2025

Related U.S. Application Data
(60) Provisional application No. 63/644,893, filed on May 9, 2024.

(51) Int. Cl. H10N 60/10; B82Y 10/00; G06N 10/40

(52) U.S. Cl. CPC H10N 60/128; G06N 10/40; H10N 60/11; B82Y 10/00

(57) ABSTRACT

Technologies for two-dimensional spin qubit arrays are disclosed. In an illustrative embodiment, a quantum processor die includes a two-dimensional array of spin qubits. Single-electron transistors (SETs) are arranged near an upper and lower boundary around the two-dimensional array of spin qubits. Each SET may be positioned to be able to read, e.g., qubits from two rows, allowing for the state of four rows of qubits to be read by the SETs above and below the array of qubits. The two-dimensional array of spin qubits may allow for a large number of physical and logical qubits in communication with each other, allowing for large scale quantum computation.

### CROSS-REFERENCE TO RELATED APPLICATIONS

This application claims the benefit of priority under 35 U.S.C. § 119(e) U.S. provisional patent application No. 63/644,893, filed May 9, 2024, and entitled “TECHNOLOGIES FOR SCALABLE SPIN QUBIT ARRAYS.” The disclosure of the prior application is considered part of and is hereby incorporated by reference in its entirety in the disclosure of this application.

### BACKGROUND

Quantum computers promise computational abilities not feasible with classical computing. One of many challenges in semiconductor quantum computing is scaling to a large number of quantum bits (qubits). Scaling the number of qubits requires an increase in the number of electrical connections to the quantum processor die as well as managing the physical arrangement of qubits and readout sensors on the quantum processor die. One approach for a small number of qubits is a linear array of qubits. However, scaling up a linear array of qubits can lead to limitations, such as an inefficient use of die space and limitations on interactions between qubits that are physically located far away from each other.

### BRIEF DESCRIPTION OF THE DRAWINGS

FIGS. 1A-1F illustrate various views of an example quantum dot device, in accordance with one embodiment.

FIG. 2 is a simplified block diagram of at least one embodiment of a quantum compute device.

FIG. 3 is a simplified block diagram of at least one embodiment of a portion of the quantum compute device of FIG. 2.

FIG. 4 illustrates an isometric view of one embodiment of a quantum processor die. FIG. 5 illustrates a top-down view of the quantum processor die of FIG. 4.

FIG. 6 illustrates an isometric view of one embodiment of an integrated circuit package including the quantum processor die of FIG. 4.

FIG. 7 illustrates a cross-sectional view of part of one embodiment of the quantum processor die of FIG. 4.

FIG. 8 illustrates a cross-sectional view of part of one embodiment of the quantum processor die of FIG. 4.

FIG. 9 illustrates a cross-sectional view of part of one embodiment of the quantum processor die of FIG. 4.

FIG. 10 illustrates a cross-sectional view of part of one embodiment of the quantum processor die of FIG. 4.

FIG. 11 illustrates a cross-sectional view of part of one embodiment of the quantum processor die of FIG. 4.

FIG. 12 illustrates a cross-sectional view of part of one embodiment of the quantum processor die of FIG. 4.

FIG. 13 illustrates a cross-sectional view of part of one embodiment of the quantum processor die of FIG. 4.

FIG. 14 illustrates a cross-sectional view of part of one embodiment of the quantum processor die of FIG. 4.

FIG. 15 illustrates a cross-sectional view of part of one embodiment of the quantum processor die of FIG. 4.

FIG. 16 illustrates a cross-sectional view of part of one embodiment of the quantum processor die of FIG. 4.

FIG. 17 is a top view of a wafer and dies, in accordance with any of the embodiments disclosed herein.

FIG. 18 is a cross-sectional side view of an integrated circuit, in accordance with any of the embodiments disclosed herein.

FIGS. 19A-19D are perspective views of example planar, gate-all-around, and stacked gate-all-around transistors.

FIG. 20 is a cross-sectional side view of an integrated circuit device assembly, in accordance with any of the embodiments disclosed herein.

FIG. 21 is a block diagram of an example electrical device, in accordance with any of the embodiments disclosed herein.

### DETAILED DESCRIPTION

In an illustrative embodiment, a quantum processor die includes a two-dimensional array of qubits, with a linear array of single-electron transistors (SETs) arranged above and below the two-dimensional array of qubits. The SETs are arranged to interact with several qubits nearby the SETs. In an illustrative embodiment, each SET can interact with qubits of two rows, allowing for a two-dimensional array of qubits with four rows of qubits. Various other embodiments are described below as well. A multi-layer interconnection stack allows for a large number of connections from the various gates to pads on the quantum processor die.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

Aspects of the disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a substrate assembly feature, such as a through width, that is described as having substantially a listed dimension can vary within a few percent of the listed dimension.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the terms “upper” /“lower” or “above” /“below” may refer to relative locations of an object (e.g., the surfaces described above), especially in light of examples shown in the attached figures, rather than an absolute location of an object. For example, an upper surface of an apparatus may be on an opposite side of the apparatus from a lower surface of the object, and the upper surface may be facing upward generally only when viewed in a particular way. As another example, a first object above a second object may be on or near an “upper” surface of the second object rather than near a “lower” surface of the object, and the first object may be truly above the second object only when the two objects are viewed in a particular way.

References are made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

A quantum computer uses quantum-mechanical phenomena such as superposition and entanglement to perform computations, simulations, or other functions. In contrast to digital computers, which store data in one of two definite states (0 or 1), quantum computation uses quantum bits (qubits), which can be in superpositions of states. Qubits may be implemented using physically distinguishable quantum states of elementary particles such as electrons and photons. For example, the polarization of a photon may be used where the two states are vertical polarization and horizontal polarization. Similarly, the spin of an electron may have distinguishable states such as “up spin” and “down spin.” Qubits in quantum mechanical systems can be in a superposition of both states at the same time, a trait that is unique and fundamental to quantum computing.

Quantum computing systems execute algorithms containing quantum logic operations performed on qubits. In some cases, the result of the algorithm is not deterministic. The quantum algorithm may be repeated many times in order to determine a statistical distribution of results or in order to have a high likelihood of finding the correct answer. In some cases, a classical algorithm may be used to check if the quantum computer determined the correct result.

Qubits have been implemented using a variety of different technologies which are capable of manipulating and reading quantum states. These include but are not limited to quantum dot devices (spin based and spatial based), trapped-ion devices, superconducting quantum computers, optical lattices, nuclear magnetic resonance computers, solid-state NMR Kane quantum devices, electrons-on-helium quantum computers, cavity quantum electrodynamics (CQED) devices, molecular magnet computers, and fullerene-based ESR quantum computers, to name a few. Thus, while a quantum dot device is described below in relation to certain embodiments of the invention, the underlying principles of the invention may be employed in combination with any type of quantum computer, including, but not limited to, those listed above. The particular physical implementation used for qubits is not necessarily required for the embodiments of the invention described herein.

Quantum dots are structures in which particles such as electrons are confined in all three dimensions. Quantum dots may confine particles based on, e.g., semiconductor layer boundaries, physical size, electric fields, magnetic fields, and/or a combination thereof. Because of the confinement, quantum dots operate according to the rules of quantum mechanics, having optical and electronic properties which differ from macroscopic entities. Quantum dots are sometimes referred to as “artificial atoms” to connote the fact that a quantum dot is a single object with discrete, bound electronic states, as is the case with atoms or molecules.

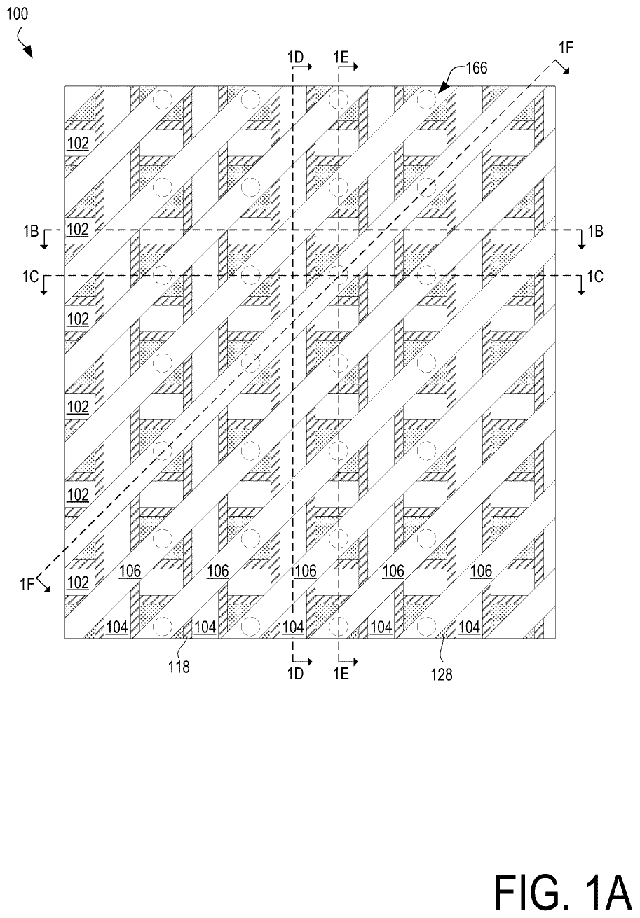

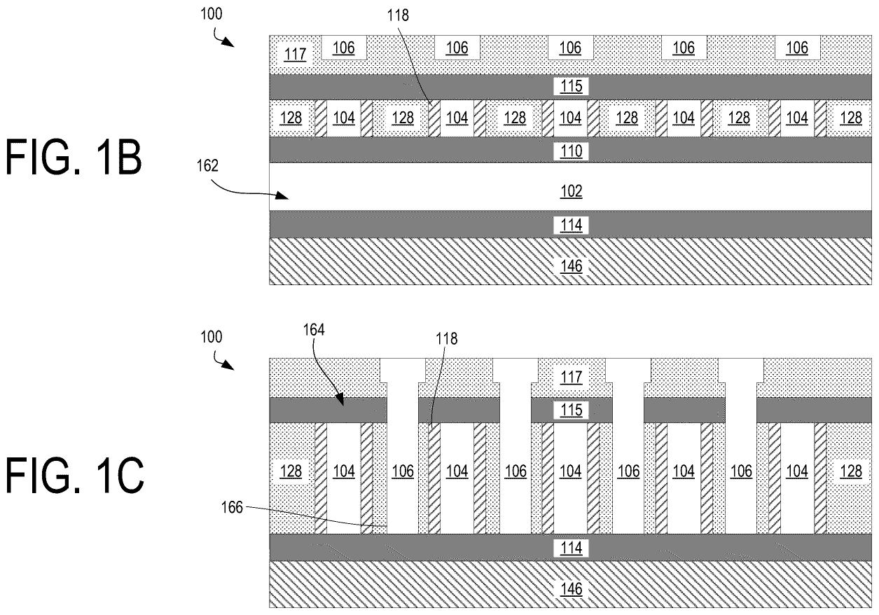

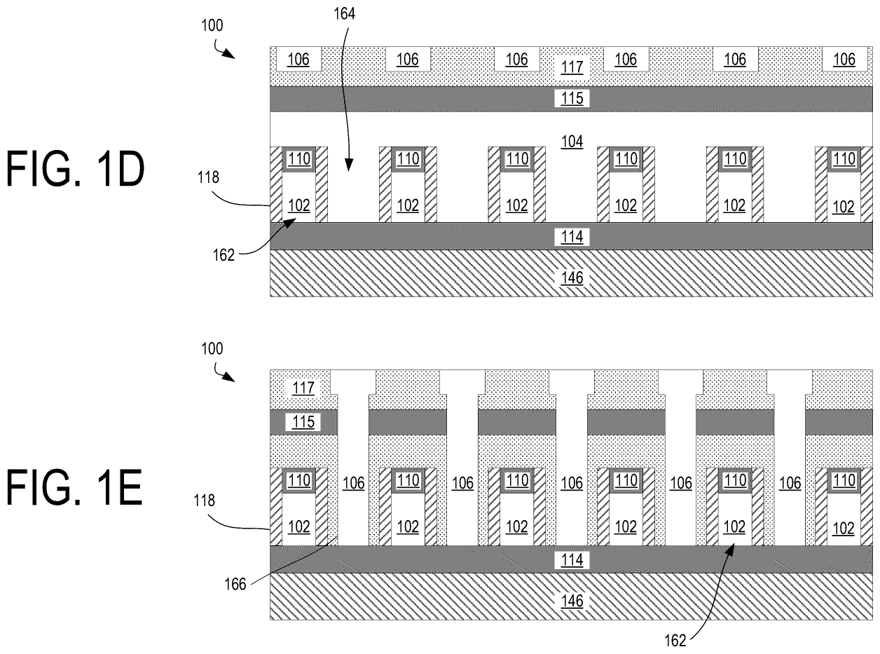

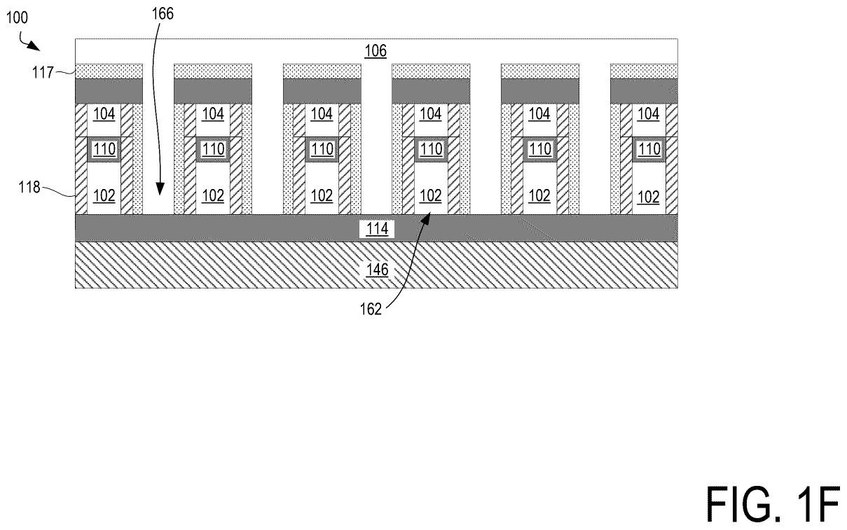

FIGS. 1A-1F are various views of a quantum dot device 100, which may be used with embodiments of the invention described below. FIG. 1A is a top view of a portion of the quantum dot device 100 with some of the materials removed so that the first gate lines 102, the second gate lines 104, and the third gate lines 106 are visible. Although many of the drawings and description herein may refer to a particular set of lines or gates as “barrier” or “quantum dot” lines or gates, respectively, this is simply for ease of discussion, and in other embodiments, the role of “barrier” and “quantum dot” lines and gates may be switched (e.g., barrier gates may instead act as quantum dot gates, and vice versa). FIGS. 1B-1F are side cross-sectional views of the quantum dot device 100 of FIG. 1A; in particular, FIG. 1B is a view through the section B-B of FIG. 1A, FIG. 1C is a view through the section C-C of FIG. 1A, FIG. 1D is a view through the section D-D of FIG. 1A, FIG. 1E is a view through the section E-E of FIG. 1A, and FIG. 1F is a view through the section F-F of FIG. 1A.

The quantum dot device 100 may include or be embodied as any suitable material, such as a die with a silicon substrate and various components patterned or built on the silicon substrate. The quantum dot device 100 of FIG. 1 may be operated in any of a number of ways. For example, in some embodiments, electrical signals such as voltages, currents, radio frequency (RF), and/or microwave signals, may be provided to one or more first gate line 102, second gate line 104, and/or third gate line 106 to cause a quantum dot (e.g., an electron spin-based quantum dot or a hole spin-based quantum dot) to form in a quantum well stack 146 under a third gate 166 of a third gate line 106. Electrical signals provided to a third gate line 106 may control the electrical potential of a quantum well under the third gates 166 of that third gate line 106, while electrical signals provided to a first gate line 102 (and/or a second gate line 104) may control the potential energy barrier under the first gates 162 of that first gate line 102 (and/or the second gates 164 of that second gate line 104) between adjacent quantum wells. Quantum interactions between quantum dots in different quantum wells in the quantum well stack 146 (e.g., under different quantum dot gates) may be controlled in part by the potential energy barrier provided by the barrier potentials imposed between them (e.g., by intervening barrier gates).

Generally, the quantum dot devices 100 disclosed herein may further include a source of magnetic fields (not shown) that may be used to create an energy difference in the states of a quantum dot (e.g., the spin states of an electron spin-based quantum dot) that are normally degenerate, and the states of the quantum dots (e.g., the spin states) may be manipulated by applying electromagnetic energy to the gates lines to create quantum bits capable of computation. The source of magnetic fields may be one or more magnet lines. Thus, the quantum dot devices 100 disclosed herein may, through controlled application of electromagnetic energy, be able to manipulate the position, number, and quantum state (e.g., spin) of quantum dots in the quantum well stack 146.

In the quantum dot device 100 of FIG. 1, a gate dielectric 114 may be disposed on a quantum well stack 146. A quantum well stack 146 may include at least one quantum well layer (not shown in FIG. 1) in which quantum dots may be localized during operation of the quantum dot device 100. The quantum well stack 146 may include, e.g., one or more alternating layers of silicon and silicon-germanium. The gate dielectric 114 may be any suitable material, such as a high-k material. Multiple parallel first gate lines 102 may be disposed on the gate dielectric 114, and spacer material 118 may be disposed on side faces of the first gate lines 102. In some embodiments, a patterned hardmask 110 may be disposed on the first gate lines 102 (with the pattern corresponding to the pattern of the first gate lines 102), and the spacer material 118 may extend up the sides of the hardmask 110, as shown. The first gate lines 102 may each be a first gate 162. Different ones of the first gate lines 102 may be electrically controlled in any desired combination (e.g., each first gate line 102 may be separately electrically controlled, or some or all the first gate lines 102 may be shorted together in one or more groups, as desired).

Multiple parallel second gate lines 104 may be disposed over and between the first gate lines 102. As illustrated in FIG. 1, the second gate lines 104 may be arranged perpendicular to the first gate lines 102. The second gate lines 104 may extend over the hardmask 110, and may include second gates 164 that extend down toward the quantum well stack 146 and contact the gate dielectric 114 between adjacent ones of the first gate lines 102, as illustrated in FIG. 1D. In some embodiments, the second gates 164 may fill the area between adjacent ones of the first gate lines 102/spacer material 118 structures; in other embodiments, an insulating material (not shown) may be present between the first gate lines 102/spacer material 118 structures and the proximate second gates 164. In some embodiments, spacer material 118 may be disposed on side faces of the second gate lines 104; in other embodiments, no spacer material 118 may be disposed on side faces of the second gate lines 104. In some embodiments, a hardmask 115 may be disposed above the second gate lines 104. Multiple ones of the second gates 164 of a second gate line 104 are electrically continuous (due to the shared conductive material of the second gate line 104 over the hardmask 110). Different ones of the second gate lines 104 may be electrically controlled in any desired combination (e.g., each second gate line 104 may be separately electrically controlled, or some or all the second gate lines 104 may be shorted together in one or more groups, as desired). Together, the first gate lines 102 and the second gate lines 104 may form a grid, as depicted in FIG. 1.

Multiple parallel third gate lines 106 may be disposed over and between the first gate lines 102 and the second gate lines 104. As illustrated in FIG. 1, the third gate lines 106 may be arranged diagonal to the first gate lines 102, and diagonal to the second gate lines 104. In particular, the third gate lines 106 may be arranged diagonally over the openings in the grid formed by the first gate lines 102 and the second gate lines 104. The third gate lines 106 may include third gates 166 that extend down to the gate dielectric 114 in the openings in the grid formed by the first gate lines 102 and the second gate lines 104; thus, each third gate 166 may be bordered by two different first gate lines 102 and two different second gate lines 104. In some embodiments, the third gates 166 may be bordered by insulating material 128; in other embodiments, the third gates 166 may fill the openings in the grid (e.g., contacting the spacer material 118 disposed on side faces of the adjacent first gate lines 102 and the second gate lines 104, not shown). Additional insulating material 117 may be disposed on and/or around the third gate lines 106. Multiple ones of the third gates 166 of a third gate line 106 are electrically continuous (due to the shared conductive material of the third gate line 106 over the first gate lines 102 and the second gate lines 104). Different ones of the third gate lines 106 may be electrically controlled in any desired combination (e.g., each third gate line 106 may be separately electrically controlled, or some or all the third gate lines 106 may be shorted together in one or more groups, as desired).

Although FIGS. 1A-F illustrate a particular number of first gate lines 102, second gate lines 104, and third gate lines 106, this is simply for illustrative purposes, and any number of first gate lines 102, second gate lines 104, and third gate lines 106 may be included in a quantum dot device 100. Other examples of arrangements of first gate lines 102, second gate lines 104, and third gate lines 106 are possible. Electrical interconnects (e.g., vias and conductive lines) may contact the first gate lines 102, second gate lines 104, and third gate lines 106 in any desired manner.

Not illustrated in FIG. 1 are accumulation regions that may be electrically coupled to the quantum well layer of the quantum well stack 146 (e.g., laterally proximate to the quantum well layer). The accumulation regions may be spaced apart from the gate lines by a thin layer of an intervening dielectric material. The accumulation regions may be regions in which carriers accumulate (e.g., due to doping, or due to the presence of large electrodes that pull carriers into the quantum well layer), and may serve as reservoirs of carriers that can be selectively drawn into the areas of the quantum well layer under the third gates 166 (e.g., by controlling the voltages on the quantum dot gates, the first gates 162, and the second gates 164) to form carrier-based quantum dots (e.g., electron or hole quantum dots, including a single charge carrier, multiple charge carriers, or no charge carriers). In other embodiments, a quantum dot device 100 may not include lateral accumulation regions, but may instead include doped layers within the quantum well stack 146. These doped layers may provide the carriers to the quantum well layer. Any combination of accumulation regions (e.g., doped or non-doped) or doped layers in a quantum well stack 146 may be used in any of the embodiments of the quantum dot devices 100 disclosed herein.

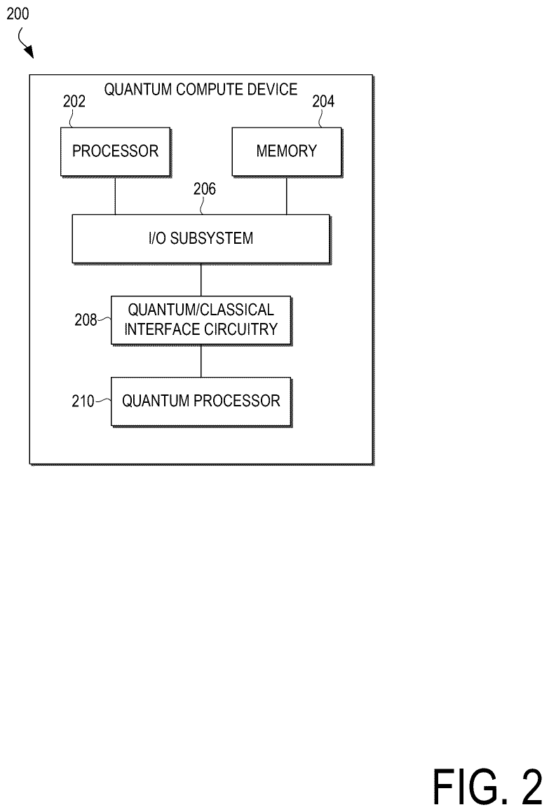

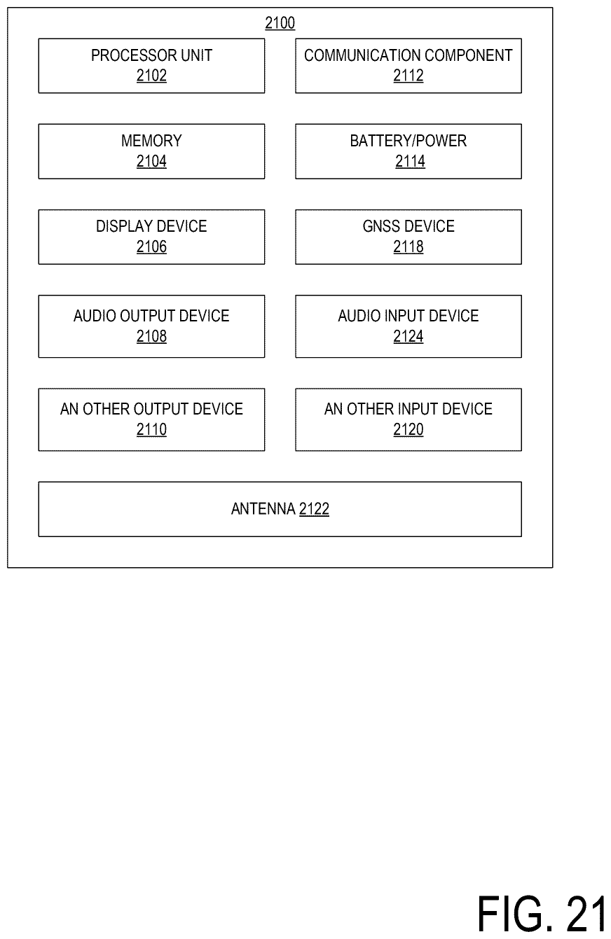

Referring now to FIG. 2, a simplified block diagram of a quantum compute device 200 is shown. In some embodiments, the quantum compute device 200 may include the quantum dot devices 100 described above in regard to FIGS. 1A-1F. The quantum compute device 200 may be embodied as or included in any type of compute device. For example, the quantum compute device 200 may include or otherwise be included in, without limitation, a server computer, an embedded computing system, a System-on-a-Chip (SoC), a multiprocessor system, a processor-based system, a consumer electronic device, a desktop computer, a laptop computer, a network device, a networked computer, a distributed computing system, and/or any other computing device. The illustrative quantum compute device 200 includes a processor 202, a memory 204, an input/output (I/O) subsystem 206, a quantum/classical interface circuitry 208, and a quantum processor 210. In some embodiments, one or more of the illustrative components of the quantum compute device 200 may be incorporated in, or otherwise form a portion of, another component. For example, the memory 204, or portions thereof, may be incorporated in the processor 202 in some embodiments. In some embodiments, the quantum compute device 200 may be embodied as the electrical device 2100 described below in regard to FIG. 21 or may include any suitable component of the electrical device 2100.

In some embodiments, the quantum compute device 200 may be located in a data center with other compute devices, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves), a micro data center, etc. In some embodiments, the quantum compute device 200 may receive jobs over a network (such as the Internet) to perform on the quantum processor 210. The quantum compute device 200 may perform the jobs on the quantum processor 210 and send the results back to the requesting device.

The processor 202 may be embodied as any type of processor capable of performing the functions described herein. For example, the processor 202 may be embodied as a single or multi-core processor(s), a single or multi-socket processor, a digital signal processor, a graphics processor, a neural network compute engine, an image processor, a microcontroller, or other processor or processing/controlling circuit. The processor 202 may include multiple processor cores. In some embodiments, the processor 202 supports quantum extensions to an existing ISA of the processor/core, allowing instructions that interface with the quantum/classical interface circuitry 208 and the quantum processor 210.

The memory 204 may be embodied as any type of volatile or non-volatile memory or data storage capable of performing the functions described herein. In operation, the memory 204 may store various data and software used during operation of the quantum compute device 200, such as operating systems, applications, programs, libraries, and drivers. The memory 204 is communicatively coupled to the processor 202 via the I/O subsystem 206, which may be embodied as circuitry and/or components to facilitate input/output operations with the processor 202, the memory 204, and other components of the quantum compute device 200. For example, the I/O subsystem 206 may be embodied as, or otherwise include, memory controller hubs, input/output control hubs, firmware devices, communication links (e.g., point-to-point links, bus links, wires, cables, light guides, printed circuit board traces, etc.) and/or other components and subsystems to facilitate the input/output operations. The I/O subsystem 206 may connect various internal and external components of the quantum compute device 200 to each other with use of any suitable connector, interconnect, bus, protocol, etc., such as an SoC fabric, PCIe®, USB2, USB3, USB4, NVMe®, Thunderbolt®, Compute Express Link (CXL), and/or the like. In some embodiments, the I/O subsystem 206 may form a portion of a system-on-a-chip (SoC) and be incorporated, along with the processor 202 and the memory 204 and other components of the quantum compute device 200 on a single integrated circuit chip.

The quantum/classical interface circuitry 208 is configured to interface with both classical components of the quantum compute device 200, such as the processor 202 and memory 204, as well as the quantum processor 210. The quantum/classical interface circuitry 208 may include a variety of analog or digital circuitry, such as analog-to-digital converters, digital-to-analog converters, high gain amplifiers, low noise amplifiers, cryogenic amplifiers, field-programmable gate arrays (FPGAs), classical processors, application-specific integrated circuits (ASICs), signal conditioning circuitry, etc. In some embodiments, some or all of the quantum/classical interface circuitry 208 may be inside of a refrigerator, such as a dilution refrigerator, a magnetic refrigerator, a helium-4 and/or helium-3 refrigerator, etc. Some or all of the components of the quantum/classical interface circuitry 208 may be at any suitable temperature, such as 10 millikelvin, 100 millikelvin, 4 Kelvin, 20 Kelvin, 77 Kelvin, room temperature or above, or anywhere in between.

The quantum processor 210 is configured to operate one or more qubits. The qubits may be any suitable type of qubit, such as a quantum dot spin qubit described above in regard to FIGS. 1A-1F. In other embodiments, the qubits may be, e.g., charge qubits, transmon qubits, microwave qubits, superconducting qubits, or any other suitable type of qubits. The quantum processor 210 may include any suitable number of physical or logical qubits, such as 1−10⁶. In the illustrative embodiment, some or all of the quantum processor 210 is in a refrigerator such as a dilution refrigerator. In particular, in the illustrative embodiment, the qubits are held at a temperature of about 10 millikelvin. In other embodiments, the qubits may be held at any suitable temperature, such as 1-100 millikelvin or higher, depending on the temperature sensitivity of the particular qubit in use.

The quantum processor 210 may be able to control the various qubits in various ways, such as by performing two-qubit gates, three-qubit gates, error correction operations, transferring a state from one type of qubit to another, measuring some, any or, all of the qubits, initializing some, any, or all of the qubits, etc.

The quantum compute device 200 may include additional components not shown in FIG. 2, such as one or more data storage devices, a network interface controller, one or more peripheral devices, etc.

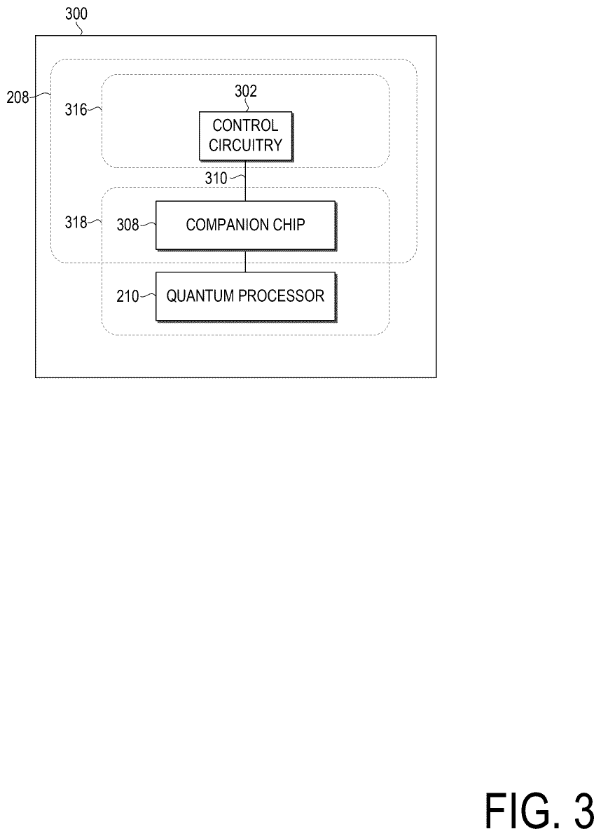

Referring now to FIG. 3, in one embodiment, the quantum processor 210 and some or all of the quantum/classical interface circuitry 208 may be in a cryogenic refrigerator 300. The quantum/classical interface circuitry 208 includes control circuitry 302 that can interface with a companion chip 308. The control circuitry 302 may be connected to the companion chip 308 by one or more wires 310. The wires 310 may be embodied as one or more cables, buses, twisted wire pairs, etc.

In the illustrative embodiment, the control circuitry 302 may be in a first stage 316 of the cryogenic refrigerator 300, and the companion chip 308 and the quantum processor 210 may be in a second stage 318 of the cryogenic refrigerator 300. In some embodiments, some or all of the control circuitry 302 may be external to the cryogenic refrigerator 300. In the illustrative embodiment, the first stage 316 is held at a temperature of about 4 Kelvin, and the second stage 318 is held at a temperature of about 20 millikelvin. In other embodiments, the first stage 316 may be held at, e.g., 1-77 Kelvin, and the second stage 318 may be held at, e.g., 10-100 millikelvin. In some embodiments, the various components of FIG. 3 may be in different stages than that shown in FIG. 3 and/or the refrigerator 300 may include additional stages, such as one or more stages at a higher or lower temperature than the first stage 316 and/or the second stage 318. The cryogenic refrigerator 300 may be any suitable refrigerator with active or passive cooling, such as a dilution refrigerator, a magnetic refrigerator, a helium-4 and/or helium-3 refrigerator, etc.

In use, the control circuitry 302 receives instructions from another component of the quantum compute device 200 (e.g., from the processor 202 or the memory 204). The instructions may be digital instructions, such as read from or write to memory, read from or write to a register, conditional branches, etc. The instructions may also be analog instructions, such as an instruction to generate or receive an analog pulse, set an analog voltage on a qubit, set a digital voltage on a multiplexer that selects a qubit, etc. The control circuitry 302 may send and receive digital and/or analog signals to the companion chip 308. Signals for multiple qubits may be sent on the wires 310 from the control circuitry 302 to the companion chip 308, and the companion chip 308 may demultiplex signals from the control circuitry 302, such as by using frequency multiplexing, temporal multiplexing, etc. As such, the control circuitry 302 may send and receive analog signals to a relatively large number of qubits over a relatively small number of wires 310. For example, for each wire 310 carrying analog signals to and from the control circuitry 302, the control circuitry 302 may control 2-100 qubits. Additionally or alternatively, in some embodiments, the control circuitry 302 may send and receive analog and/or digital signals directly to or from the quantum processor 210, without necessarily going through the companion chip 308.

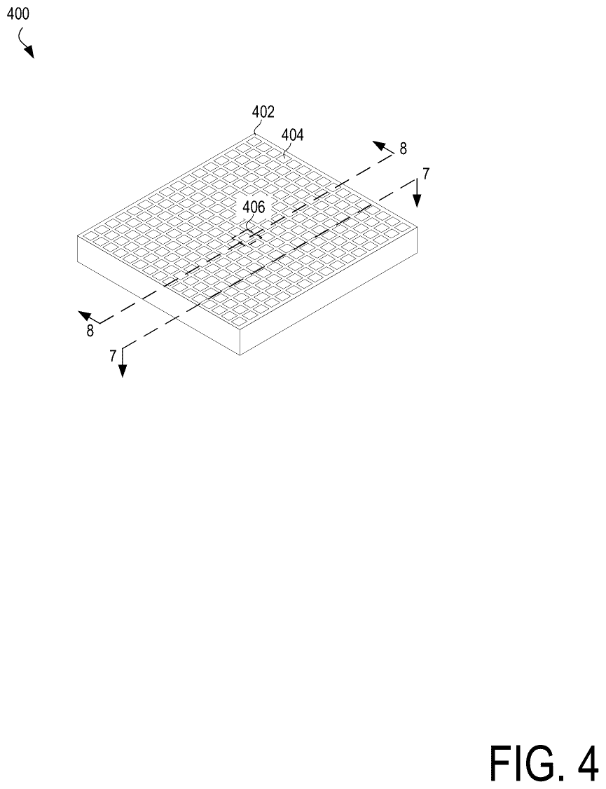

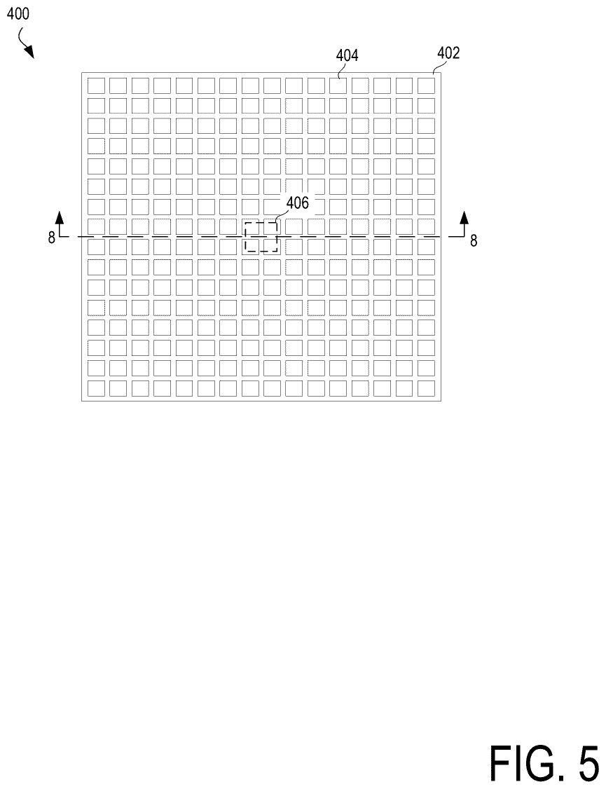

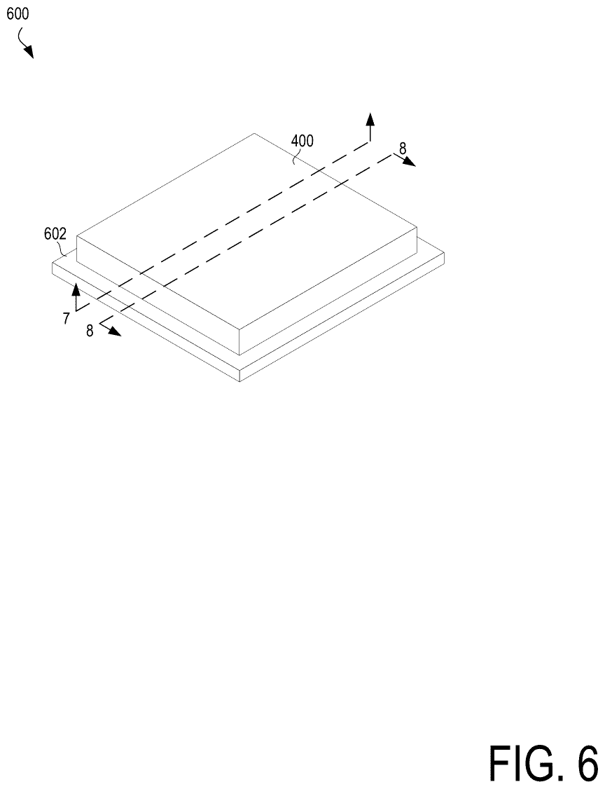

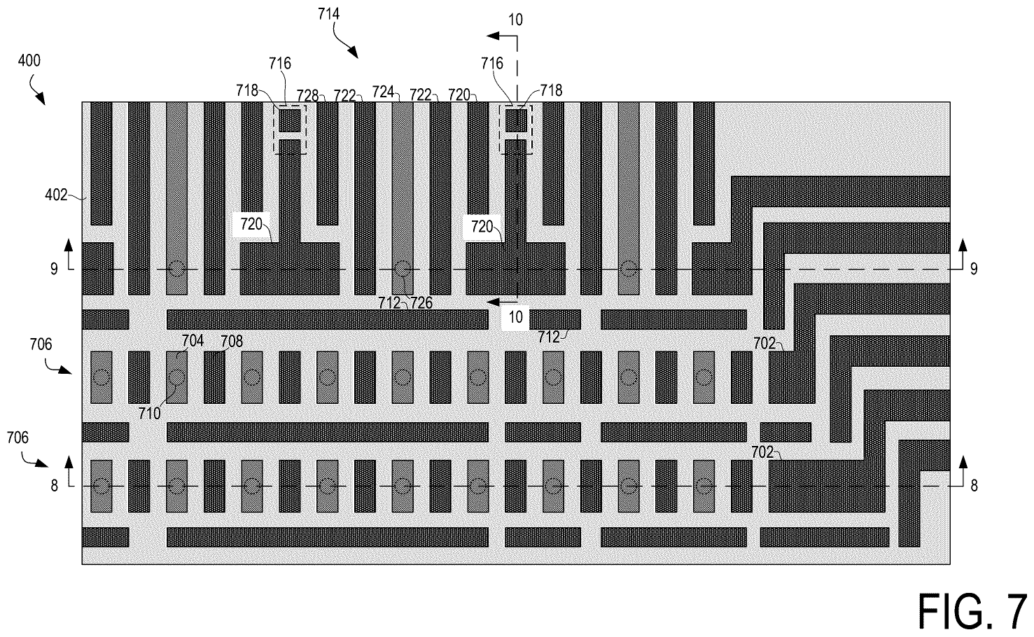

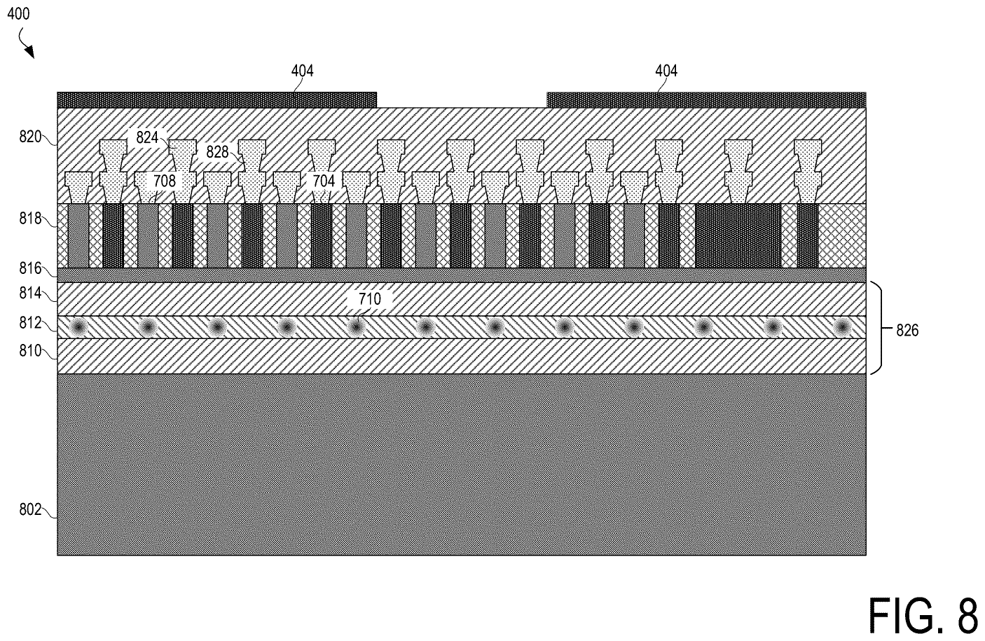

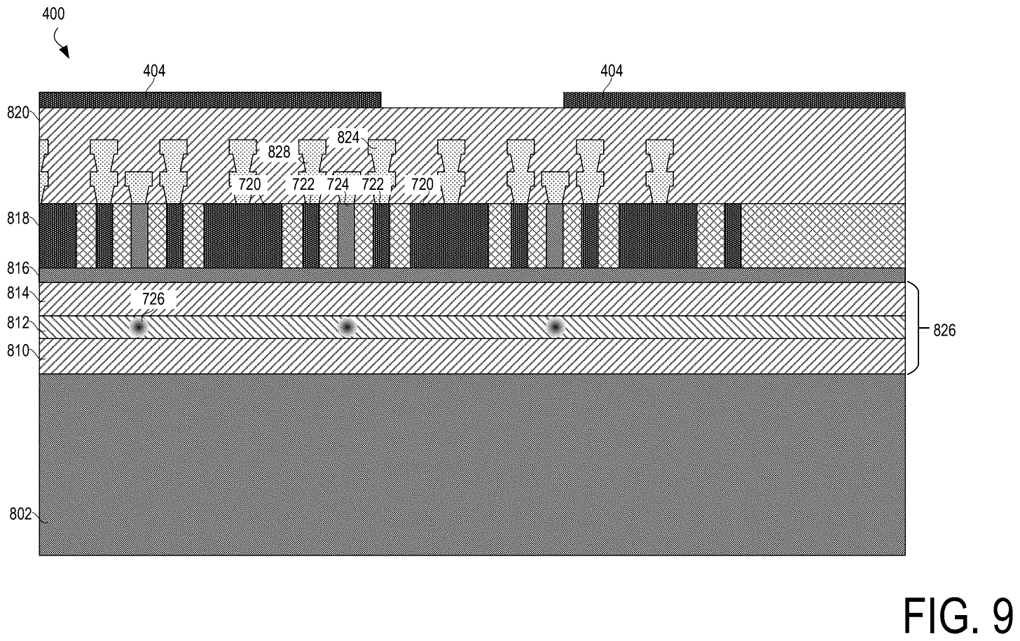

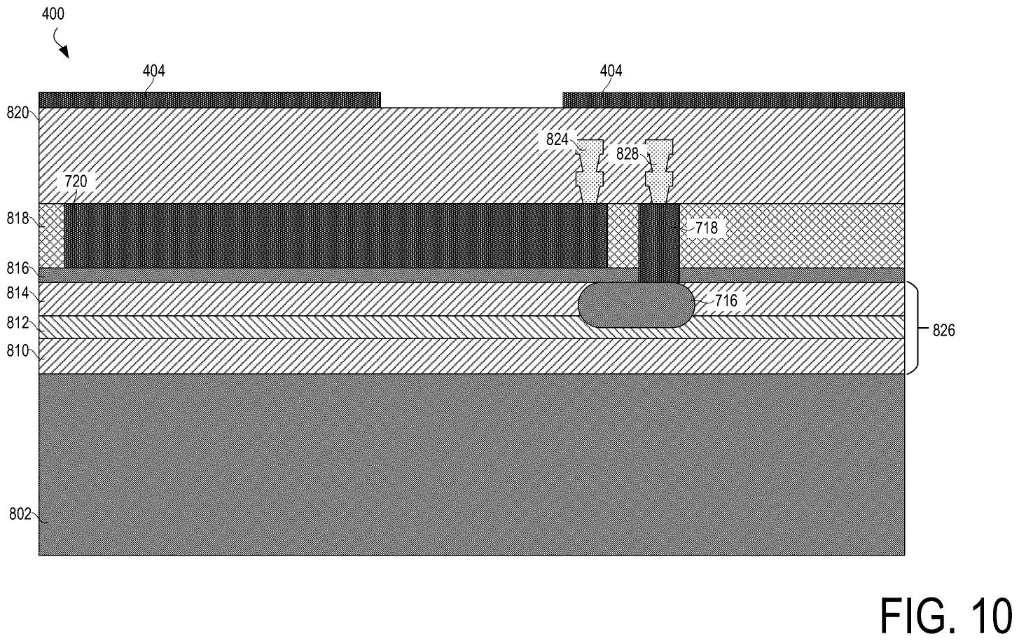

Referring now to FIGS. 4-10, in one embodiment, a quantum processor die 400 includes a substrate 402, an array of pads 404 on a surface of the die 400, and a region 406 of the die in which qubits are defined. FIG. 4 shows an isometric view of the quantum processor die 400. FIG. 5 shows a top-down view of the quantum processor die 400. FIG. 6 shows an isometric view of an integrated circuit package 600 that includes the quantum processor die 400. FIGS. 7 and 8 show cross-sectional view of the quantum processor die 400, taken from the views 7 and 8, respectively, denoted in FIGS. 4 and 6. FIGS. 9 and 10 show cross-sectional view of the quantum processor die 400, taken from the views 9 and 10, respectively, denoted in FIG. 7.

The substrate 402 of the quantum processor die 400 may be any suitable material, such as silicon or other semiconductor. The quantum processor die 400 may include any suitable number of pads 404, such as 10-10,000. In an illustrative embodiment, the pads 404 are arranged in a two-dimensional array, as shown in FIG. 4. In other embodiments, some or all of the pads 404 may be arranged linearly or in one or more staggered rows, such as around an edge of the quantum processor die 400. The various pads 404 may be connected through one or more interconnect layers to various gates of the quantum processor die 400. The quantum processor die 400 may have any suitable dimensions, such as a length or width of 0.2-30 millimeters and a thickness of 0.05-5 millimeters. In an illustrative embodiment, the region 406 of the quantum processor die 400 in which the qubits are located may be relatively small compared to the overall size of the quantum processor die, such as a length and/or width of 1-100,000 micrometers. In some embodiments, the quantum processor die 400 may include more than one linear array of qubits in different regions of the quantum processor die 400, such as 2-5,000 linear arrays. In some embodiments, the various linear arrays may be coupled together using one or more quantum dots, allowing for coherent quantum communication between different linear arrays.

Referring now to FIG. 6, the quantum processor die 400 may be mounted on a circuit board 602 to form an integrated circuit package 600, such as by being flip-chip mounted to the circuit board 602 and connected by solder bumps. Additionally or alternatively, in some embodiments, the quantum processor die 400 may be wire bonded to traces or pads on the circuit board 602. The circuit board 602 may be any suitable material, such as FR-4. The circuit board 602 may have any suitable width or length, such as a width and/or length of 1-200 millimeters. The integrated circuit package 600 may include additional components not shown in FIG. 6, such as one or more additional dies, one or more traces, one or more wire bonds, etc. In an illustrative embodiment, the array of pads 404 on the quantum processor die 400 may interface with a corresponding array on the circuit board 602. Additionally or alternatively, in some embodiments, some or all of pads 404 on the quantum processor die 400 may be connected to the circuit board 602 through, e.g., wire bonds or other suitable connecting scheme.

Referring now to FIG. 7, in one embodiment, a top-down view of a cross-section of part of the quantum processor die 400 is shown. In an illustrative embodiment, the view shown in FIG. 7 corresponds to part of the region 406 of the quantum processor die 400. In one embodiment, FIG. 7 may show one corner of an array of quantum dots 710. An expanded view of one embodiment showing the full array of quantum dots 710 is shown in FIG. 16. In one example, a two-dimensional array of quantum dots 710 may include four rows of quantum dots 710, extending for, e.g., 4-1,000 columns of quantum dots 710. In other embodiments, a two-dimensional array of quantum dots 710 may include any suitable number of rows of quantum dots 710, such as 2-16 rows.

FIG. 7 shows rows 706 of quantum dots 710. Each quantum dot 710 is defined, in part, by a plunger gate 704 above the quantum dot 710, one or more barrier gates 708, and one or more screening gates 712, 728. In an illustrative embodiment, each quantum dot 710 is used as a qubit. Additionally or alternatively, in other embodiments, a physical qubit may be made up of, e.g., two or three quantum dots 710. For example, in one embodiment, a physical qubit may be embodied as an exchange-only qubit composed of three quantum dots 710, with one electron in each quantum dot 710. The quantum processor die 400 may include any suitable number of quantum dots 710 per row 706, such as a 4-1,000, and may include any suitable number of rows 706 of quantum dots 710, such as 4-16.

Above a boundary defining the rows 706 quantum dots 710, in an illustrative embodiment, are single-electron transistors (SETs) 714. Another row of SETs 714 may be positioned below a boundary defining the rows 706 of quantum dots 710, as shown in FIG. 16. As used herein, a single-electron transistor includes few-electron transistors and does not necessarily operate in the single-electron regime unless explicitly stated otherwise, despite the name. Each illustrative SET 714 is able to perform a readout on one or more nearby quantum dots 710, such as the nearest 3-5 quantum dots 710 in the first two rows 706 closes to the SET 714. In some embodiments, each SET 714 may be able to perform readout on, e.g., the nearest 1-10 quantum dots 710 in the first, e.g., 2-8 rows closest to the SET 714. In an illustrative embodiment, each SET 714 includes a pair of ohmic contacts 718 coupled to an implant region 716, a pair of accumulator gates 720, a pair of barrier gates 722, and a plunger gate 724. The various gates of the SET 714 define a quantum dot 726 under the plunger gate 724. The SET 714 is described below in more detail in regard to FIGS. 9 and 10.

It should be appreciated that FIG. 7 shows only part of the quantum processor die 400, and the array of quantum dots 710 may continue down and left, from the perspective of FIG. 7. As shown in the figure, the SETs 714 are external to the array of quantum dots 710 but can reach two or more rows 706 of quantum dots 710, allowing for, e.g., four rows of quantum dots 710 with a large number of quantum dots 710 per row while also allowing for each quantum dot 710 to be near to an SET 714 for a readout. In some embodiments, one advantage of the approach described above is straightforward scaling for a multi-layer interconnect stack. As the interconnects are spread out linearly along the rows 706 of quantum dots 710, only a relatively small number of interconnect layers (e.g., 1-5) is required to fan out connections from the various gates 704, 708, 712, 720, 722, 724, 728.

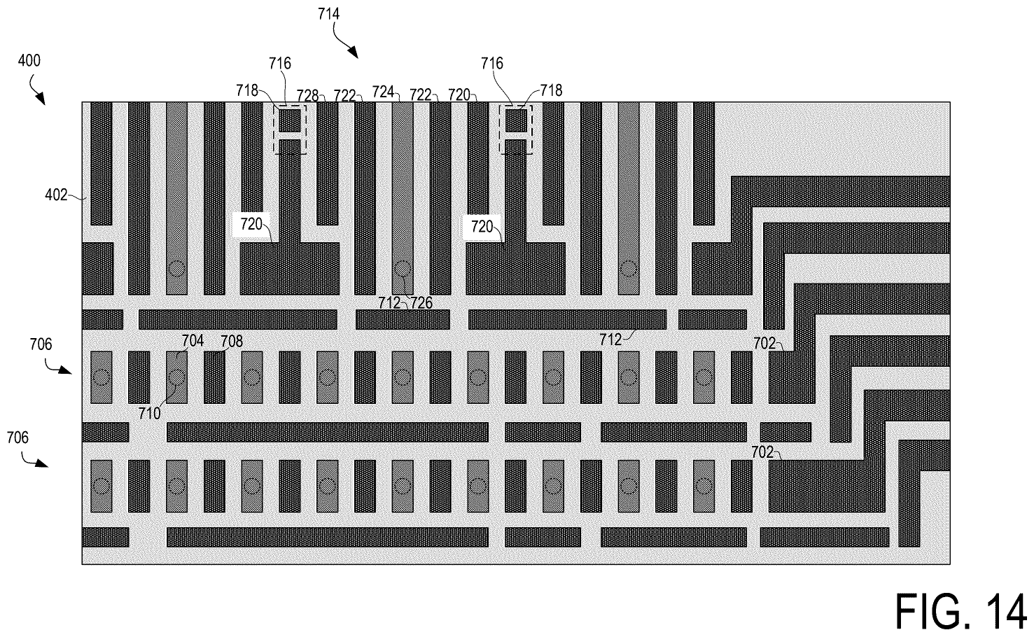

In some embodiments, another advantage of the approach described above is straightforward loading of electrons into the quantum dots 710. During initialization, an electron must be loaded into each of the quantum dots 710. One possible approach is to load the electrons in from the side, such as from the reservoirs 702. With a large array, such an approach can take a long time to initialize all of the quantum dots 710. However, in some embodiments, part of the SETs 714 (such as the accumulator gates 720, the quantum dots 726, the barrier gates 722, etc.) may be used to load electrons into the qubits in parallel from the top and bottom of the array, initializing the quantum dots 710 with electrons much more quickly. In such embodiments, electrons may be loaded from the quantum dot 726, through the region below the screening gate 712 positioned directly in from of the quantum dot 726, as shown in FIG. 14.

Referring now to FIG. 8, in an illustrative embodiment, a cross-sectional side view of the quantum processor die 400 is shown. The quantum processor die 400 includes several layers and structure within the layers. In one embodiment, the quantum processor die 400 includes a silicon layer 802, a silicon-germanium (SiGe) layer 810 (i.e., layer 810 comprises predominantly silicon and germanium atoms), a silicon layer 812, a SiGe layer 814, a dielectric layer 816, a dielectric layer 818, and one or more interconnect layers 820. In some embodiments, the quantum processor die 400 may include more, fewer, or different layers than those shown in FIG. 8. For example, in one embodiment, the layer 812 may be a germanium layer 812. As used herein, SiGe refers to an alloy with a molecular formula of Si₁₋ₓGeₓ, where x may be any value between 10% and 90%, depending on the particular structure and function required. Any SiGe layer or region described herein may have 10% to 90% germanium by number of atoms unless a different range is explicitly required. In an illustrative embodiment, the SiGe layers 810, 814 are 25%-35% (or about 30%) germanium by number of atoms.

In an illustrative embodiment, the SiGe layer 810, silicon layer 812, and SiGe layer 814 form a stack 826 that defines a quantum well. Quantum dots 710 are defined in the silicon layer 812. The quantum dots 710 are defined by the quantum well and the electric and/or magnetic fields provided by the various gates 708, 704, 712 above the stack 826. For example, plunger gates 708 with positive voltages may alternate with barrier gates 704 with negative voltages to form an electrostatic potential for quantum dots 710 under the plunger gates 708. The screening gates 712 may provide electrostatic confinement into and out of the page, from the perspective of FIG. 8. The quantum dots 710 may be manipulated in any suitable manner, such as static or dynamic electric or magnetic fields on the various gates 704, 708, 712, interactions with other quantum dots 710 such as exchange interactions, interactions with the SETs 714 through readout operations, etc.

The various gates 704, 708, 712, 720, 722, 728, etc., may be connected to suitable voltage and/or current sources using appropriate traces and interconnects. For example, interconnect layers 820 may include several layers of pads or traces 824 and vias 828. In an illustrative embodiment, connections to different gates 704, 708, 712, 720, 722, 728, etc., may be routed in different layers, allowing for each gate 704, 708, 712, 720, 722, 728, etc., to be routed to a different pad 404 on the surface of the quantum processor die 400. In some embodiments, some of the gates 704, 708, 712, 720, 722, 728 shown in FIG. 7 may be connected together, such as some of the screening gates 712, which may reduce the number of pads 404 on the quantum processor die 400. Additionally or alternatively, in some embodiment, the quantum processor die 400 may include, e.g., multiplexing or similar circuitry in order to allow for one pad 404 to provide a signal to more than one gate 704, 708, 712, 720, 722, 728, etc.

The various gates 704, 708, 712, 720, 722, 728, etc., vias 828, traces 824, etc., may be any suitable conductive material or combination of materials, such as tungsten, titanium, niobium, copper, gold, polysilicon, aluminum, palladium, etc. In some embodiments, traces that may carry relatively high current densities may be embodied as superconducting material and operate below a superconducting temperature for that material.

The dielectric layers 816, 818 and the dielectric in the interconnect layer 820 may be any suitable dielectric, such as silicon oxide, hafnium oxide, aluminum oxide, titanium oxide, a combination thereof, and/or the like. In one illustrative embodiment, the dielectric layer 816 is a high-k dielectric, such as hafnium oxide. In some embodiments, the quantum processor die 400 may include more or fewer layers than those shown in the figures. For example, in some embodiments, the dielectric layer 816 may be combined with the dielectric layer 818.

The various layers of the quantum processor die 400 may have any suitable thickness. For example, the silicon layer 812 and the SiGe layers 810, 814 may have a thickness of 5-5000 nanometers. The various dielectric layers such as dielectric layers 816, 818 may have any suitable thickness, such as 5-5000 nanometers. The interconnect layers 820 may include any suitable number of layers or levels of interconnects, such as 1-20. The interconnect layers 820 may have any suitable thickness, such as 50 nanometers to 1 millimeter. The quantum dots 710 and/or the may have any suitable pitch, such as 30-200 nanometers. The various gates, such as the gates 704, 708, 712, 720, 722, 728, etc., may have any suitable dimensions depending on, e.g., the anticipated applied voltage or current, such as a cross-sectional length or width of 10-500 nanometers. The rows 706 of the quantum dots 710 may have any suitable pitch, such as 40-1,000 nanometers.

It should be appreciated that the components shown in the quantum processor die 400 are merely some of the components, and the quantum processor die 400, the quantum processor package 600, and/or other connected circuitry may include additional components or layers not shown. For example, radiofrequency and/or microwave frequency sources may be coupled to traces and used to set, reset, or otherwise control quantum dots 710 or groups of quantum dots 710, including for two-or multi-qubit operations. The quantum processor die 400 may include any or all of the suitable features of the quantum dot device 100 described above in regard to FIGS. 1A-1F. The quantum processor die 400 may include quantum dots 710 defined in a different manner as the quantum dots 710 defined in the stack 826, such as a fin of a semiconductor material (e.g., silicon) surrounded on some or all sides by a dielectric. In some embodiments, the quantum processor die 400, the quantum processor package 600, and/or another component may apply other static or dynamic electric or magnetic fields. For example, in one embodiment, a magnetic field gradient is applied across some or all of the array of quantum dots 710, such as by an electromagnet or permanent magnet near, on, or in the quantum processor die 400.

Referring now to FIG. 9, in one embodiment, a cross-sectional view of one embodiment of an SET 714 is shown. The illustrative SET 714 includes a pair of ohmic contacts 718 coupled to an implant region 716, a pair of accumulator gates 720, a pair of barrier gates 722, and a plunger gate 724. The ohmic contacts 718 and the implant regions 716 are visible in FIG. 10 but are not visible in FIG. 9. The various gates of the SET 714 define a quantum dot 726 under the plunger gate 724. The quantum dot 726 may have any suitable length and/or width, such as 5-200 nanometers. It should be appreciated that a longer quantum dot 726 may be sensitive to more quantum dots 710.

Referring now to FIG. 10, in one embodiment, a cross-sectional view of part of one embodiment of an SET 714 is shown. FIG. 10 shows an accumulator gate 720, an ohmic contact 718, and an implant region 716. In an illustrative embodiment, a voltage applied to the accumulator gate 720 establishes a 2-dimensional electron (or hole) gas in the silicon layer 812 of the stack 826 under the accumulator gate 720. The implant region 716 is heavily doped and galvanically coupled to the ohmic contact 718, allowing electrons to flow from the 2-dimensional electron (or hole) gas to the ohmic contact 718. In some embodiments, the implant region 716 is relatively far from the quantum dot 726, such as 0.3-2 micrometers. In other embodiments, the implant region 716 may be closer to the quantum dot 726, such as 0.05-0.3 micrometers.

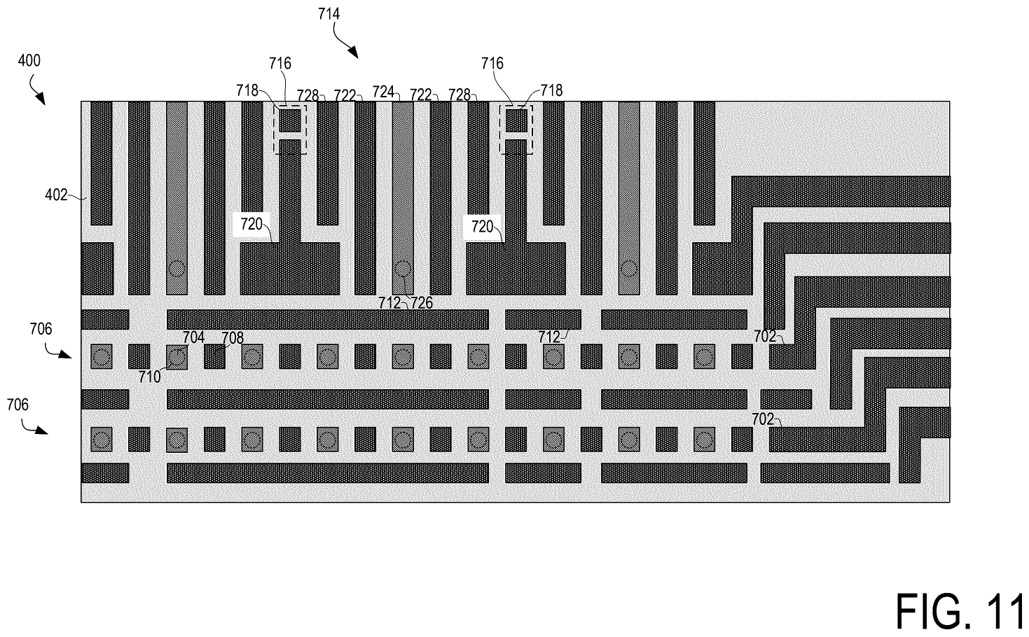

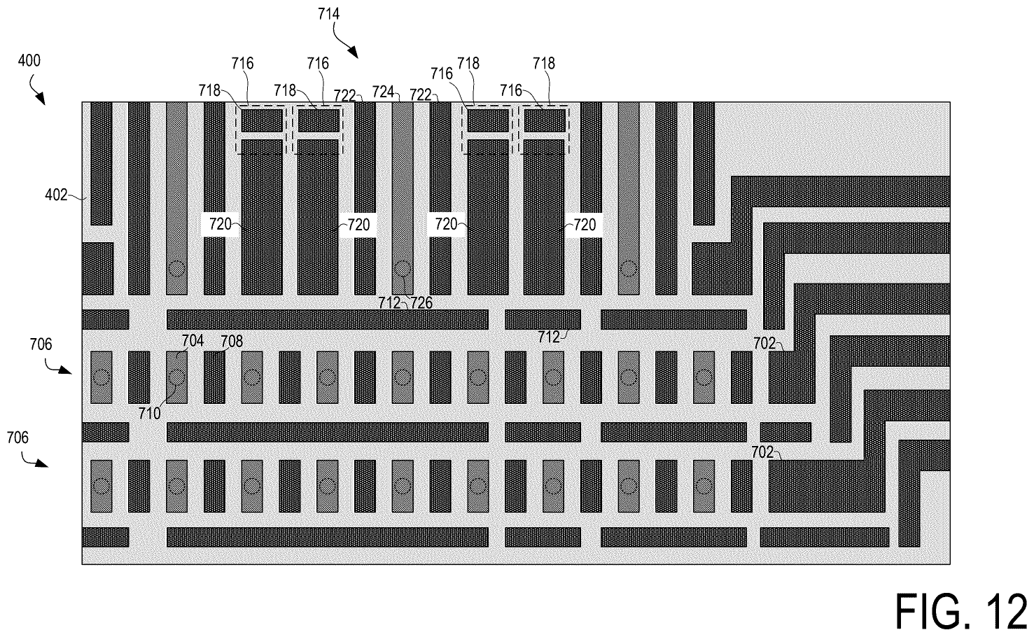

It should be appreciated that the configuration described above is merely one possible embodiment, and other embodiments are envisioned as well. For example, in an illustrative embodiment, there may be one SET 714 for each three quantum dots 710 in the row 706 closest to the SET 714. Additionally or alternatively, in some embodiments, there may be one SET 714 for every 1-5 quantum dots 710 in the row 706. In another example, as shown in FIG. 11, one embodiment of a quantum processor die 400 may include plunger gates 704 and/or barrier gates 708 that are closer to square. For example, the plunger gates 704 and/or barrier gates 708 may have a ratio of the width to the length of, e.g., 0.8-1.2. In the illustrative embodiment, an SET 714 may share one or more accumulator gates 720 and/or one or more ohmic contacts with adjacent SETs 714. Such an approach may allow for a reduced number of connections to the quantum processor die 400, at the cost of not being able to read from every SET 714 simultaneously. Additionally or alternatively, as shown in FIG. 12, in one embodiment, each SET 714 may have dedicated accumulator gates 720. Such an approach may allow for a faster readout, as each SET 714 may be read simultaneously. In some embodiments, two or more SETs 714 may be used to perform a readout on a single qubit or quantum dot 710. In some cases, some or all of the SETs 714 may be monitored continuously to measure the charge state of the quantum dots 710 in the vicinity. It should be appreciated that, in general, each quantum dot 710 has one electron in it, and it is only when a measurement is performed that the spin state of the electrons is transferred to a charge state, such as by lowering the barrier gate 708 between adjacent quantum dots 710.

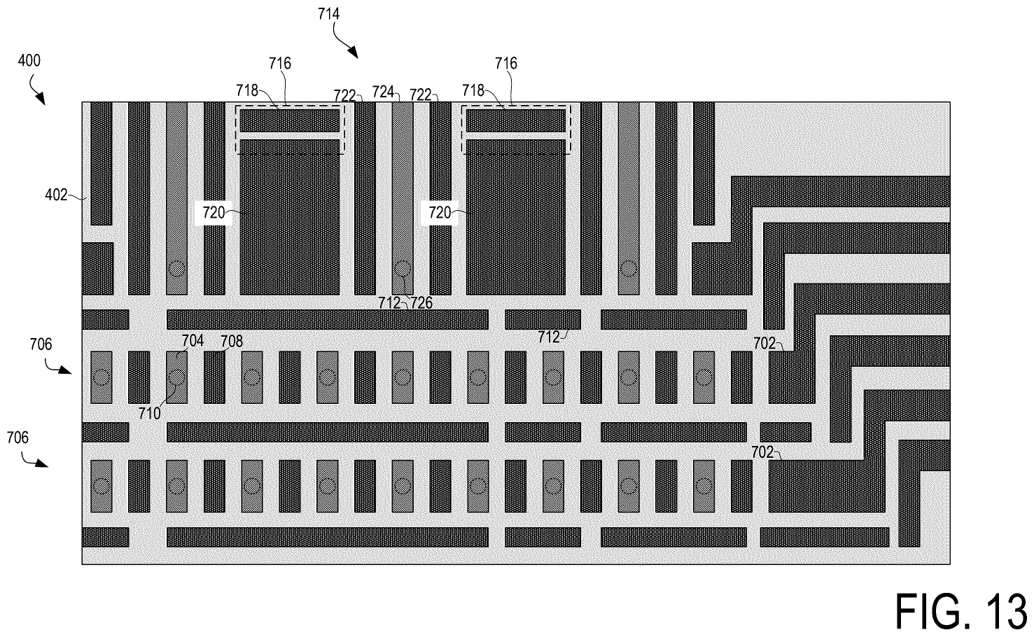

In the illustrative embodiment described above in regard to FIG. 7, the accumulation gate 720 has a “T” shape, with a relatively large width near the quantum dot 726, and a narrow width towards the ohmic contact 718. In some embodiments, the entire accumulator gate 720 may have a relatively large width, as shown in FIG. 13. The wider accumulator gate 720 establishes a larger 2-dimensional electron (or hole) gas, reducing the resistance for electrons in flowing in the gas.

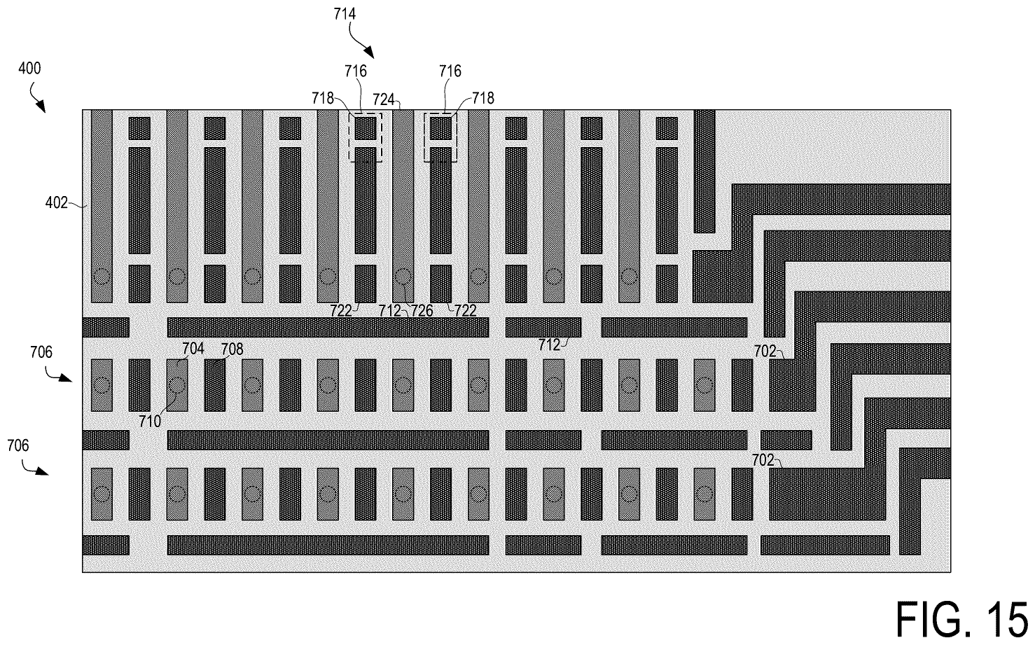

In the illustrative embodiment described above in regard to FIG. 7, the SET 714 has two accumulation gates 720, two barrier gates, and a plunger gate 724 arranged collinearly with the quantum dot 726. In some embodiments, a different configuration may be used, such as barrier gates 722 that are below the accumulator gates 716, as shown in FIG. 15.

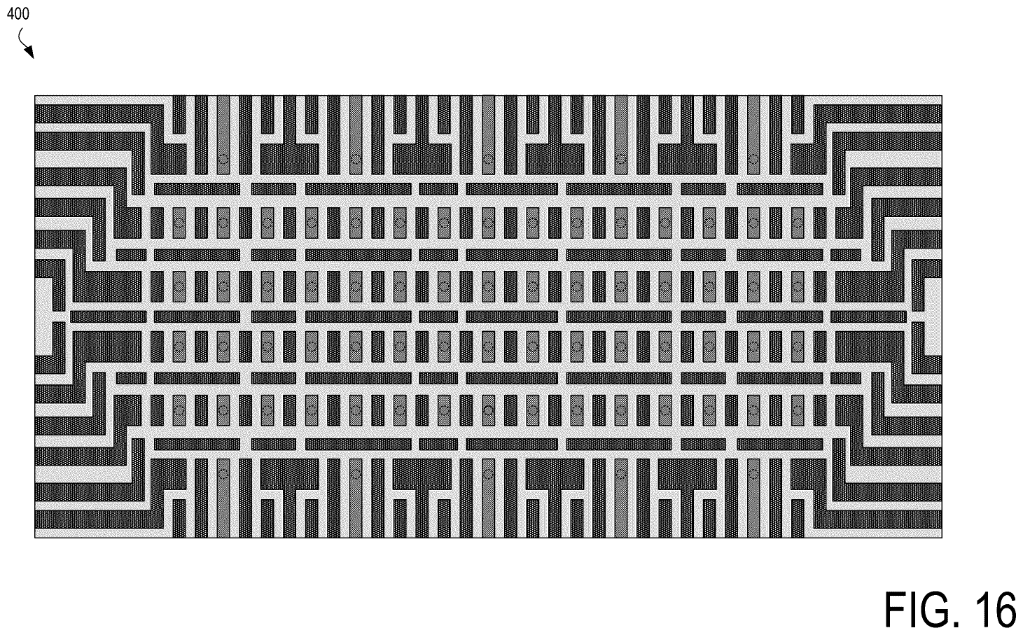

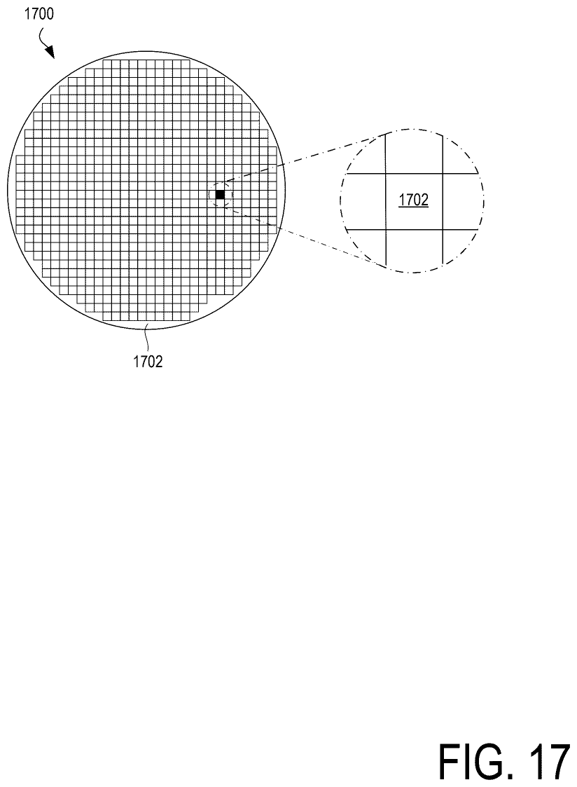

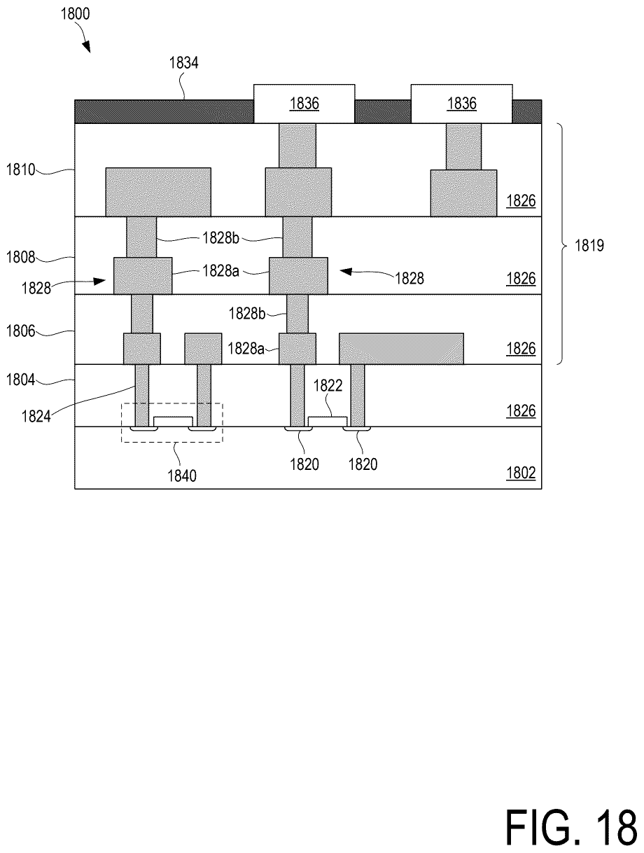

FIG. 17 is a top view of a wafer 1700 and dies 1702 that may be included in any of the integrated circuit packages 600 disclosed herein (e.g., as any suitable ones of the dies 400). The wafer 1700 may be composed of semiconductor material and may include one or more dies 1702 having integrated circuit structures formed on a surface of the wafer 1700. The individual dies 1702 may be a repeating unit of an integrated circuit product that includes any suitable integrated circuit. After the fabrication of the semiconductor product is complete, the wafer 1700 may undergo a singulation process in which the dies 1702 are separated from one another to provide discrete “chips” of the integrated circuit product. The die 1702 may be any of the dies 400 disclosed herein. The die 1702 may include one or more transistors (e.g., some of the transistors 1840 of FIG. 18, discussed below), supporting circuitry to route electrical signals to the transistors, passive components (e.g., signal traces, resistors, capacitors, or inductors), and/or any other integrated circuit components. In some embodiments, the wafer 1700 or the die 1702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1702. For example, a memory array formed by multiple memory devices may be formed on a same die 1702 as a processor unit (e.g., the processor unit 2102 of FIG. 21) or other logic that is configured to store information in the memory devices or execute instructions stored in the memory array. Various ones of the integrated circuit packages 600 disclosed herein may be manufactured using a die-to-wafer assembly technique in which some dies 400 are attached to a wafer 1700 that include others of the dies 400, and the wafer 1700 is subsequently singulated.

FIG. 18 is a cross-sectional side view of an integrated circuit device 1800 that may be included in any of the integrated circuit packages 600 disclosed herein (e.g., in any of the dies 400). One or more of the integrated circuit devices 1800 may be included in one or more dies 1702 (FIG. 17). The integrated circuit device 1800 may be formed on a die substrate 1802 (e.g., the wafer 1700 of FIG. 17) and may be included in a die (e.g., the die 1702 of FIG. 17). The die substrate 1802 may be a semiconductor substrate composed of semiconductor material systems including, for example, n-type or p-type materials systems (or a combination of both). The die substrate 1802 may include, for example, a crystalline substrate formed using a bulk silicon or a silicon-on-insulator (SOI) substructure. In some embodiments, the die substrate 1802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1802. Although a few examples of materials from which the die substrate 1802 may be formed are described here, any material that may serve as a foundation for an integrated circuit device 1800 may be used. The die substrate 1802 may be part of a singulated die (e.g., the dies 1702 of FIG. 17) or a wafer (e.g., the wafer 1700 of FIG. 17).

The integrated circuit device 1800 may include one or more device layers 1804 disposed on the die substrate 1802. The device layer 1804 may include features of one or more transistors 1840 (e.g., metal oxide semiconductor field-effect transistors (MOSFETs)) formed on the die substrate 1802. The transistors 1840 may include, for example, one or more source and/or drain (S/D) regions 1820, a gate 1822 to control current flow between the S/D regions 1820, and one or more S/D contacts 1824 to route electrical signals to/from the S/D regions 1820. The transistors 1840 may include additional features not depicted for the sake of clarity, such as device isolation regions, gate contacts, and the like. The transistors 1840 are not limited to the type and configuration depicted in FIG. 18 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

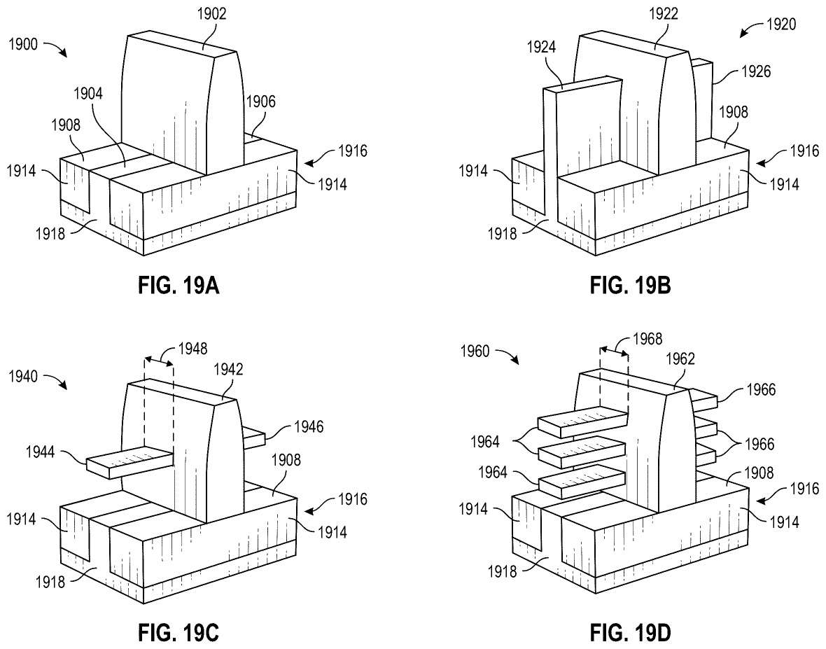

FIGS. 19A-19D are simplified perspective views of example planar, FinFET, gate-all-around, and stacked gate-all-around transistors. The transistors illustrated in FIGS. 19A-19D are formed on a substrate 1916 having a surface 1908. Isolation regions 1914 separate the source and drain regions of the transistors from other transistors and from a bulk region 1918 of the substrate 1916.

FIG. 19A is a perspective view of an example planar transistor 1900 comprising a gate 1902 that controls current flow between a source region 1904 and a drain region 1906. The transistor 1900 is planar in that the source region 1904 and the drain region 1906 are planar with respect to the substrate surface 1908.

FIG. 19B is a perspective view of an example FinFET transistor 1920 comprising a gate 1922 that controls current flow between a source region 1924 and a drain region 1926. The transistor 1920 is non-planar in that the source region 1924 and the drain region 1926 comprise “fins” that extend upwards from the substrate surface 1908. As the gate 1922 encompasses three sides of the semiconductor fin that extends from the source region 1924 to the drain region 1926, the transistor 1920 can be considered a tri-gate transistor. FIG. 19B illustrates one S/D fin extending through the gate 1922, but multiple S/D fins can extend through the gate of a FinFET transistor.

FIG. 19C is a perspective view of a gate-all-around (GAA) transistor 1940 comprising a gate 1942 that controls current flow between a source region 1944 and a drain region 1946. The transistor 1940 is non-planar in that the source region 1944 and the drain region 1946 are elevated from the substrate surface 1908.

FIG. 19D is a perspective view of a GAA transistor 1960 comprising a gate 1962 that controls current flow between multiple elevated source regions 1964 and multiple elevated drain regions 1966. The transistor 1960 is a stacked GAA transistor as the gate controls the flow of current between multiple elevated S/D regions stacked on top of each other. The transistors 1940 and 1960 are considered gate-all-around transistors as the gates encompass all sides of the semiconductor portions that extends from the source regions to the drain regions. The transistors 1940 and 1960 can alternatively be referred to as nanowire, nanosheet, or nanoribbon transistors depending on the width (e.g., widths 1948 and 1968 of transistors 1940 and 1960, respectively) of the semiconductor portions extending through the gate.

Returning to FIG. 18, a transistor 1840 may include a gate 1822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1840 along the source-channel-drain direction, the gate electrode may consist of a U-shaped structure that includes a bottom portion substantially parallel to the surface of the die substrate 1802 and two sidewall portions that are substantially perpendicular to the top surface of the die substrate 1802. In other embodiments, at least one of the metal layers that form the gate electrode may simply be a planar layer that is substantially parallel to the top surface of the die substrate 1802 and does not include sidewall portions substantially perpendicular to the top surface of the die substrate 1802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1820 may be formed within the die substrate 1802 adjacent to the gate 1822 of individual transistors 1840. The S/D regions 1820 may be formed using an implantation/diffusion process or an etching/deposition process, for example. In the former process, dopants such as boron, aluminum, antimony, phosphorous, or arsenic may be ion-implanted into the die substrate 1802 to form the S/D regions 1820. An annealing process that activates the dopants and causes them to diffuse farther into the die substrate 1802 may follow the ion-implantation process. In the latter process, the die substrate 1802 may first be etched to form recesses at the locations of the S/D regions 1820. An epitaxial deposition process may then be carried out to fill the recesses with material that is used to fabricate the S/D regions 1820. In some implementations, the S/D regions 1820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1820 may be formed using one or more alternate semiconductor materials such as germanium or a group III-V material or alloy. In further embodiments, one or more layers of metal and/or metal alloys may be used to form the S/D regions 1820.

Electrical signals, such as power and/or input/output (I/O) signals, may be routed to and/or from the devices (e.g., transistors 1840) of the device layer 1804 through one or more interconnect layers disposed on the device layer 1804 (illustrated in FIG. 18 as interconnect layers 1806-1810). For example, electrically conductive features of the device layer 1804 (e.g., the gate 1822 and the S/D contacts 1824) may be electrically coupled with the interconnect structures 1828 of the interconnect layers 1806-1810. The one or more interconnect layers 1806-1810 may form a metallization stack (also referred to as an “ILD stack”) 1819 of the integrated circuit device 1800.

The interconnect structures 1828 may be arranged within the interconnect layers 1806-1810 to route electrical signals according to a wide variety of designs; in particular, the arrangement is not limited to the particular configuration of interconnect structures 1828 depicted in FIG. 18. Although a particular number of interconnect layers 1806-1810 is depicted in FIG. 18, embodiments of the present disclosure include integrated circuit devices having more or fewer interconnect layers than depicted.

In some embodiments, the interconnect structures 1828 may include lines 1828a and/or vias 1828b filled with an electrically conductive material such as a metal. The lines 1828a may be arranged to route electrical signals in a direction of a plane that is substantially parallel with a surface of the die substrate 1802 upon which the device layer 1804 is formed. For example, the lines 1828a may route electrical signals in a direction in and out of the page and/or in a direction across the page. The vias 1828b may be arranged to route electrical signals in a direction of a plane that is substantially perpendicular to the surface of the die substrate 1802 upon which the device layer 1804 is formed. In some embodiments, the vias 1828b may electrically couple lines 1828a of different interconnect layers 1806-1810 together.

The interconnect layers 1806-1810 may include a dielectric material 1826 disposed between the interconnect structures 1828, as shown in FIG. 18. In some embodiments, dielectric material 1826 disposed between the interconnect structures 1828 in different ones of the interconnect layers 1806-1810 may have different compositions; in other embodiments, the composition of the dielectric material 1826 between different interconnect layers 1806-1810 may be the same. The device layer 1804 may include a dielectric material 1826 disposed between the transistors 1840 and a bottom layer of the metallization stack as well. The dielectric material 1826 included in the device layer 1804 may have a different composition than the dielectric material 1826 included in the interconnect layers 1806-1810; in other embodiments, the composition of the dielectric material 1826 in the device layer 1804 may be the same as a dielectric material 1826 included in any one of the interconnect layers 1806-1810.

A first interconnect layer 1806 (referred to as Metal 1 or “M1”) may be formed directly on the device layer 1804. In some embodiments, the first interconnect layer 1806 may include lines 1828a and/or vias 1828b, as shown. The lines 1828a of the first interconnect layer 1806 may be coupled with contacts (e.g., the S/D contacts 1824) of the device layer 1804. The vias 1828b of the first interconnect layer 1806 may be coupled with the lines 1828a of a second interconnect layer 1808.

The second interconnect layer 1808 (referred to as Metal 2 or “M2”) may be formed directly on the first interconnect layer 1806. In some embodiments, the second interconnect layer 1808 may include via 1828b to couple the interconnect structures 1828 of the second interconnect layer 1808 with the lines 1828a of a third interconnect layer 1810. Although the lines 1828a and the vias 1828b are structurally delineated with a line within individual interconnect layers for the sake of clarity, the lines 1828a and the vias 1828b may be structurally and/or materially contiguous (e.g., simultaneously filled during a dual-damascene process) in some embodiments.

The third interconnect layer 1810 (referred to as Metal 3 or “M3”) (and additional interconnect layers, as desired) may be formed in succession on the second interconnect layer 1808 according to similar techniques and configurations described in connection with the second interconnect layer 1808 or the first interconnect layer 1806. In some embodiments, the interconnect layers that are “higher up” in the metallization stack 1819 in the integrated circuit device 1800 (i.e., farther away from the device layer 1804) may be thicker that the interconnect layers that are lower in the metallization stack 1819, with lines 1828a and vias 1828b in the higher interconnect layers being thicker than those in the lower interconnect layers.

The integrated circuit device 1800 may include a solder resist material 1834 (e.g., polyimide or similar material) and one or more conductive contacts 1836 formed on the interconnect layers 1806-1810. In FIG. 18, the conductive contacts 1836 are illustrated as taking the form of bond pads. The conductive contacts 1836 may be electrically coupled with the interconnect structures 1828 and configured to route the electrical signals of the transistor(s) 1840 to external devices. For example, solder bonds may be formed on the one or more conductive contacts 1836 to mechanically and/or electrically couple an integrated circuit die including the integrated circuit device 1800 with another component (e.g., a printed circuit board). The integrated circuit device 1800 may include additional or alternate structures to route the electrical signals from the interconnect layers 1806-1810; for example, the conductive contacts 1836 may include other analogous features (e.g., posts) that route the electrical signals to external components. The conductive contacts 1836 may serve as the conductive contacts or pads 404, as appropriate.

In some embodiments in which the integrated circuit device 1800 is a double-sided die, the integrated circuit device 1800 may include another metallization stack (not shown) on the opposite side of the device layer(s) 1804. This metallization stack may include multiple interconnect layers as discussed above with reference to the interconnect layers 1806-1810, to provide conductive pathways (e.g., including conductive lines and vias) between the device layer(s) 1804 and additional conductive contacts (not shown) on the opposite side of the integrated circuit device 1800 from the conductive contacts 1836. These additional conductive contacts may serve as the conductive contacts or pads 404, as appropriate.

In other embodiments in which the integrated circuit device 1800 is a double-sided die, the integrated circuit device 1800 may include one or more through silicon vias (TSVs) through the die substrate 1802; these TSVs may make contact with the device layer(s) 1804, and may provide conductive pathways between the device layer(s) 1804 and additional conductive contacts (not shown) on the opposite side of the integrated circuit device 1800 from the conductive contacts 1836. These additional conductive contacts may serve as the conductive contacts or pads 404, as appropriate. In some embodiments, TSVs extending through the substrate can be used for routing power and ground signals from conductive contacts on the opposite side of the integrated circuit device 1800 from the conductive contacts 1836 to the transistors 1840 and any other components integrated into the die, and the metallization stack 1819 can be used to route I/O signals from the conductive contacts 1836 to transistors 1840 and any other components integrated into the die.

Multiple integrated circuit devices 1800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

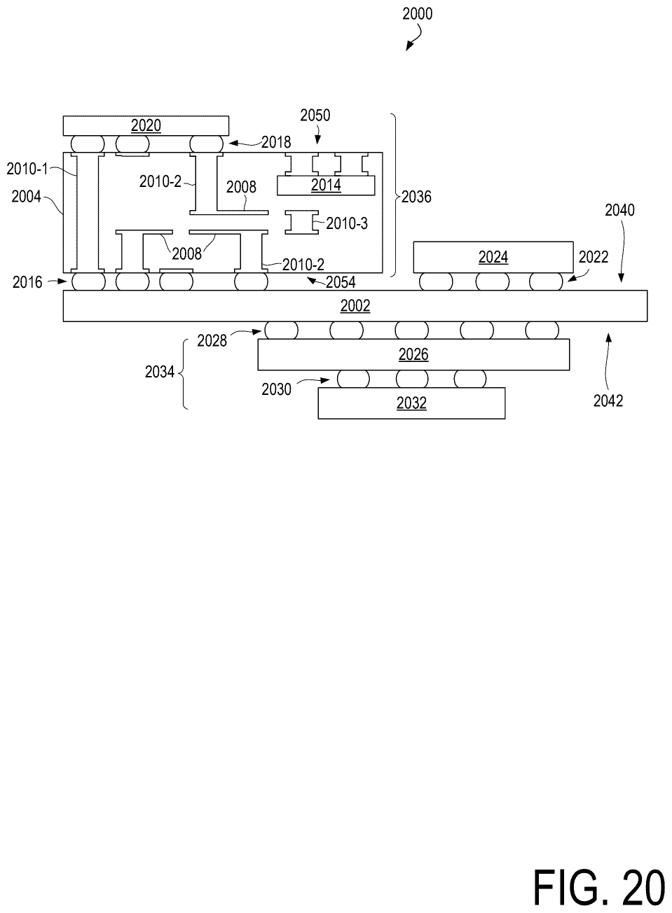

FIG. 20 is a cross-sectional side view of an integrated circuit device assembly 2000 that may include any of the integrated circuit packages 600 disclosed herein. In some embodiments, the integrated circuit device assembly 2000 may be an integrated circuit package 600. The integrated circuit device assembly 2000 includes a number of components disposed on a circuit board 2002 (which may be a motherboard, system board, mainboard, etc.). The integrated circuit device assembly 2000 includes components disposed on a first face 2040 of the circuit board 2002 and an opposing second face 2042 of the circuit board 2002; generally, components may be disposed on one or both faces 2040 and 2042. Any of the integrated circuit components discussed below with reference to the integrated circuit device assembly 2000 may take the form of any suitable ones of the embodiments of the integrated circuit packages 600 disclosed herein.

In some embodiments, the circuit board 2002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2002. In other embodiments, the circuit board 2002 may be a non-PCB substrate. In some embodiments the circuit board 2002 may be, for example, the circuit board 602. The integrated circuit device assembly 2000 illustrated in FIG. 20 includes a package-on-interposer structure 2036 coupled to the first face 2040 of the circuit board 2002 by coupling components 2016. The coupling components 2016 may electrically and mechanically couple the package-on-interposer structure 2036 to the circuit board 2002, and may include solder balls (as shown in FIG. 20), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 2016 may serve as the coupling components illustrated or described for any of the substrate assembly or substrate assembly components described herein, as appropriate.

The package-on-interposer structure 2036 may include an integrated circuit component 2020 coupled to an interposer 2004 by coupling components 2018. The coupling components 2018 may take any suitable form for the application, such as the forms discussed above with reference to the coupling components 2016. Although a single integrated circuit component 2020 is shown in FIG. 20, multiple integrated circuit components may be coupled to the interposer 2004; indeed, additional interposers may be coupled to the interposer 2004. The interposer 2004 may provide an intervening substrate used to bridge the circuit board 2002 and the integrated circuit component 2020.

The integrated circuit component 2020 may be a packaged or unpacked integrated circuit product that includes one or more integrated circuit dies (e.g., the die 1702 of FIG. 17, the integrated circuit device 1800 of FIG. 18) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2020, a single monolithic integrated circuit die comprises solder bumps attached to contacts on the die. The solder bumps allow the die to be directly attached to the interposer 2004. The integrated circuit component 2020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2004 may spread connections to a wider pitch or reroute a connection to a different connection. For example, the interposer 2004 may couple the integrated circuit component 2020 to a set of ball grid array (BGA) conductive contacts of the coupling components 2016 for coupling to the circuit board 2002. In the embodiment illustrated in FIG. 20, the integrated circuit component 2020 and the circuit board 2002 are attached to opposing sides of the interposer 2004; in other embodiments, the integrated circuit component 2020 and the circuit board 2002 may be attached to a same side of the interposer 2004. In some embodiments, three or more components may be interconnected by way of the interposer 2004.

In some embodiments, the interposer 2004 may be formed as a PCB, including multiple metal layers separated from one another by layers of dielectric material and interconnected by electrically conductive vias. In some embodiments, the interposer 2004 may be formed of an epoxy resin, a fiberglass-reinforced epoxy resin, an epoxy resin with inorganic fillers, a ceramic material, or a polymer material such as polyimide. In some embodiments, the interposer 2004 may be formed of alternate rigid or flexible materials that may include the same materials described above for use in a semiconductor substrate, such as silicon, germanium, and other group III-V and group IV materials. The interposer 2004 may include metal interconnects 2008 and vias 2010-1, 1810-2, 1810-3, including but not limited to through hole vias 2010-1 (that extend from a first face 2050 of the interposer 2004 to a second face 2054 of the interposer 2004), blind vias 2010-2 (that extend from the first or second faces 2050 or 2054 of the interposer 2004 to an internal metal layer), and buried vias 2010-3 (that connect internal metal layers).

In some embodiments, the interposer 2004 can comprise a silicon interposer. Through silicon vias (TSV) extending through the silicon interposer can connect connections on a first face of a silicon interposer to an opposing second face of the silicon interposer. In some embodiments, an interposer 2004 comprising a silicon interposer can further comprise one or more routing layers to route connections on a first face of the interposer 2004 to an opposing second face of the interposer 2004.

The interposer 2004 may further include embedded devices 2014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2004. The package-on-interposer structure 2036 may take the form of any of the package-on-interposer structures known in the art.

The integrated circuit device assembly 2000 may include an integrated circuit component 2024 coupled to the first face 2040 of the circuit board 2002 by coupling components 2022. The coupling components 2022 may take the form of any of the embodiments discussed above with reference to the coupling components 2016, and the integrated circuit component 2024 may take the form of any of the embodiments discussed above with reference to the integrated circuit component 2020.

The integrated circuit device assembly 2000 illustrated in FIG. 20 includes a package-on-package structure 2034 coupled to the second face 2042 of the circuit board 2002 by coupling components 2028. The package-on-package structure 2034 may include an integrated circuit component 2026 and an integrated circuit component 2032 coupled together by coupling components 2030 such that the integrated circuit component 2026 is disposed between the circuit board 2002 and the integrated circuit component 2032. The coupling components 2028 and 2030 may take the form of any of the embodiments of the coupling components 2016 discussed above, and the integrated circuit components 2026 and 2032 may take the form of any of the embodiments of the integrated circuit component 2020 discussed above. The package-on-package structure 2034 may be configured in accordance with any of the package-on-package structures known in the art.

FIG. 21 is a block diagram of an example electrical device 2100 that may include one or more of the integrated circuit packages 600 or quantum compute devices 200 disclosed herein. For example, any suitable ones of the components of the electrical device 2100 may include one or more of the integrated circuit device assemblies 2000, integrated circuit components 2020, integrated circuit devices 1800, or integrated circuit dies 1702 disclosed herein, and may be arranged in any of the integrated circuit packages 600 disclosed herein. A number of components are illustrated in FIG. 21 as included in the electrical device 2100, but any one or more of these components may be omitted or duplicated, as suitable for the application. In some embodiments, some or all of the components included in the electrical device 2100 may be attached to one or more motherboards mainboards, or system boards. In some embodiments, one or more of these components are fabricated onto a single system-on-a-chip (SoC) die.

Additionally, in various embodiments, the electrical device 2100 may not include one or more of the components illustrated in FIG. 21, but the electrical device 2100 may include interface circuitry for coupling to the one or more components. For example, the electrical device 2100 may not include a display device 2106, but may include display device interface circuitry (e.g., a connector and driver circuitry) to which a display device 2106 may be coupled. In another set of examples, the electrical device 2100 may not include an audio input device 2124 or an audio output device 2108, but may include audio input or output device interface circuitry (e.g., connectors and supporting circuitry) to which an audio input device 2124 or audio output device 2108 may be coupled.

The electrical device 2100 may include one or more processor units 2102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2100 may include a memory 2104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2104 may include memory that is located on the same integrated circuit die as the processor unit 2102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2100 can comprise one or more processor units 2102 that are heterogeneous or asymmetric to another processor unit 2102 in the electrical device 2100. There can be a variety of differences between the processing units 2102 in a system in terms of a spectrum of metrics of merit including architectural, microarchitectural, thermal, power consumption characteristics, and the like. These differences can effectively manifest themselves as asymmetry and heterogeneity among the processor units 2102 in the electrical device 2100.

In some embodiments, the electrical device 2100 may include a communication component 2112 (e.g., one or more communication components). For example, the communication component 2112 can manage wireless communications for the transfer of data to and from the electrical device 2100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2112 may operate in accordance with other wireless protocols in other embodiments. The electrical device 2100 may include an antenna 2122 to facilitate wireless communications and/or to receive other wireless communications (such as AM or FM radio transmissions).

In some embodiments, the communication component 2112 may manage wired communications, such as electrical, optical, or any other suitable communication protocols (e.g., IEEE 802.3 Ethernet standards). As noted above, the communication component 2112 may include multiple communication components. For instance, a first communication component 2112 may be dedicated to shorter-range wireless communications such as Wi-Fi or Bluetooth, and a second communication component 2112 may be dedicated to longer-range wireless communications such as global positioning system (GPS), EDGE, GPRS, CDMA, WiMAX, LTE, EV-DO, or others. In some embodiments, a first communication component 2112 may be dedicated to wireless communications, and a second communication component 2112 may be dedicated to wired communications.

The electrical device 2100 may include battery/power circuitry 2114. The battery/power circuitry 2114 may include one or more energy storage devices (e.g., batteries or capacitors) and/or circuitry for coupling components of the electrical device 2100 to an energy source separate from the electrical device 2100 (e.g., AC line power).

The electrical device 2100 may include a display device 2106 (or corresponding interface circuitry, as discussed above). The display device 2106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2100 may include an audio output device 2108 (or corresponding interface circuitry, as discussed above). The audio output device 2108 may include any embedded or wired or wirelessly connected external device that generates an audible indicator, such as speakers, headsets, or earbuds.

The electrical device 2100 may include an audio input device 2124 (or corresponding interface circuitry, as discussed above). The audio input device 2124 may include any embedded or wired or wirelessly connected device that generates a signal representative of a sound, such as microphones, microphone arrays, or digital instruments (e.g., instruments having a musical instrument digital interface (MIDI) output). The electrical device 2100 may include a Global Navigation Satellite System (GNSS) device 2118 (or corresponding interface circuitry, as discussed above), such as a Global Positioning System (GPS) device. The GNSS device 2118 may be in communication with a satellite-based system and may determine a geolocation of the electrical device 2100 based on information received from one or more GNSS satellites, as known in the art.

The electrical device 2100 may include an other output device 2110 (or corresponding interface circuitry, as discussed above). Examples of the other output device 2110 may include an audio codec, a video codec, a printer, a wired or wireless transmitter for providing information to other devices, or an additional storage device.

The electrical device 2100 may include an other input device 2120 (or corresponding interface circuitry, as discussed above). Examples of the other input device 2120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2100 may be any other electronic device that processes data. In some embodiments, the electrical device 2100 may comprise multiple discrete physical components. Given the range of devices that the electrical device 2100 can be manifested as in various embodiments, in some embodiments, the electrical device 2100 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a quantum well layer defined in a quantum processor die; a two-dimensional array of plunger gates to establish a two-dimensional array of quantum dots in the quantum well layer, wherein the two-dimensional array of plunger gates is defined by an upper boundary and a lower boundary; a first linear array of single-electron transistors (SETS), wherein the first linear array of SETs is disposed along the upper boundary; and a second linear array of single-electron transistors (SETS), wherein the second linear array of SETs is disposed along the lower boundary.

Example 2 includes the subject matter of Example 1, and wherein the two-dimensional array of plunger gates comprises four rows of plunger gates.

Example 3 includes the subject matter of any of Examples 1 and 2, and wherein the two-dimensional array of plunger gates comprises a plurality of rows of plunger gates, wherein individual SETs of the two-dimensional array of the SETs are sensitive to a plurality of qubits corresponding to two or more rows of the plurality of rows of plunger gates.

Example 4 includes the subject matter of any of Examples 1-3, and wherein individual SETs of the first linear array of SETs and second linear array of SETs comprise a first ohmic contact, a first accumulator gate, a first barrier gate, a plunger gate, a second barrier gate, a second accumulator gate, and a second ohmic contact.

Example 5 includes the subject matter of any of Examples 1-4, and wherein the first accumulator gate of individual SETs of at least some of the first linear array of SETs and the second linear array of SETs is shared with an adjacent SET, wherein the second accumulator gate of individual SETs of at least some of the first linear array of SETs and the second linear array of SETs is shared with an adjacent SET.

Example 6 includes the subject matter of any of Examples 1-5, and wherein the first accumulator gate of individual SETs of the first linear array of SETs and the second linear array of SETs is dedicated to the individual SETs, wherein the second accumulator gate of individual SETs of the first linear array of SETs and the second linear array of SETs is dedicated to the individual SETs.

Example 7 includes the subject matter of any of Examples 1-6, and wherein, from a top-down perspective, a ratio of a width to a length of individual plunger gates of the two-dimensional array of plunger gates is between 0.8 and 1.2.

Example 8 includes the subject matter of any of Examples 1-7, and wherein, in use, one or more components of individual SETs of the first linear array of SETs and the second linear array of SETs are used to load electrons into the two-dimensional array of quantum dots.

Example 9 includes the subject matter of any of Examples 1-8, and wherein individual quantum dots of the two-dimensional array of quantum dots are coupled to every other quantum dot of the two-dimensional array of quantum dots by zero or more intermediate quantum dots of the two-dimensional array of quantum dots.

Example 10 includes the subject matter of any of Examples 1-9, and further including quantum/classical interface circuitry coupled to the two-dimensional array of plunger gates; and a processor coupled to the quantum/classical interface circuitry.

Example 11 includes an apparatus comprising a stack comprising a plurality of semiconductor layers, the plurality of semiconductor layers defining a quantum well in the stack; a two-dimensional array of plunger gates to establish a two-dimensional array of quantum dots in the quantum well; a first single-electron transistor (SET), wherein, from a top-down perspective, individual quantum dots of the two-dimensional array of quantum dots are below the first SET; and a second single-electron transistor (SET), wherein, from the top-down perspective, individual quantum dots of the two-dimensional array of quantum dots are above the second SET.

Example 12 includes the subject matter of Example 11, and wherein the two-dimensional array of plunger gates comprises four rows of plunger gates.

Example 13 includes the subject matter of any of Examples 11 and 12, and wherein the first SET comprises a first ohmic contact, a first accumulator gate, a first barrier gate, a plunger gate, a second barrier gate, a second accumulator gate, and a second ohmic contact.

Example 14 includes the subject matter of any of Examples 11-13, and wherein the first accumulator gate is shared with an adjacent SET, wherein the second accumulator gate is shared with an adjacent SET.

Example 15 includes the subject matter of any of Examples 11-14, and wherein the first accumulator gate of the first SET is dedicated to the first SET, wherein the second accumulator gate of the first SET is dedicated to the first SET.

Example 16 includes the subject matter of any of Examples 11-15, and wherein, from a top-down perspective, a ratio of a width to a length of individual plunger gates of the two-dimensional array of plunger gates is between 0.8 and 1.2.

Example 17 includes the subject matter of any of Examples 11-16, and wherein, in use, one or more components of the first SET and the second SET are used to load electrons into the two-dimensional array of quantum dots.

Example 18 includes the subject matter of any of Examples 11-17, and wherein individual quantum dots of the two-dimensional array of quantum dots are coupled to every other quantum dot of the two-dimensional array of quantum dots by zero or more intermediate quantum dots of the two-dimensional array of quantum dots.

Example 19 includes the subject matter of any of Examples 11-18, and further including quantum/classical interface circuitry coupled to the two-dimensional array of quantum dots; and a processor coupled to the quantum/classical interface circuitry.

Example 20 includes an apparatus comprising a plurality of gates for establishing a two-dimensional array of quantum dots in a quantum well of a quantum processor die, wherein the two-dimensional array of quantum dots comprises at least four rows of quantum dots and at least four columns of quantum dots; and a plurality of gates for performing a readout on any quantum dot in the two-dimensional array of quantum dots.

Example 21 includes the subject matter of Example 20, and wherein the plurality of gates for establishing a two-dimensional array of quantum dots comprises a plurality of rows of plunger gates, wherein the plurality of gates for performing a readout are able to perform a readout on quantum dots in two or more rows of the plurality of rows of plunger gates.

Example 22 includes the subject matter of any of Examples 20 and 21, and wherein the plurality of gates for performing a readout comprises a plurality of single-electron transistors (SETs), wherein individual SETs of the plurality of SETs comprise a first ohmic contact, a first accumulator gate, a first barrier gate, a plunger gate, a second barrier gate, a second accumulator gate, and a second ohmic contact.

Example 23 includes the subject matter of any of Examples 20-22, and wherein the first accumulator gate of individual SETs of at least some of the plurality of SETs is shared with an adjacent SET, wherein the second accumulator gate of individual SETs of at least some of the plurality of SETs is shared with an adjacent SET.

Example 24 includes the subject matter of any of Examples 20-23, and wherein the first accumulator gate of individual SETs of the plurality of SETs is dedicated to the individual SETs, wherein the second accumulator gate of individual SETs of the plurality of SETs is dedicated to the individual SETs.

Example 25 includes the subject matter of any of Examples 20-24, and wherein, from a top-down perspective, a ratio of a width to a length of individual plunger gates of the plurality of gates for establishing a two-dimensional array of quantum dots is between 0.8 and 1.2.

Example 26 includes the subject matter of any of Examples 20-25, and wherein, in use, one or more components of individual SETs of the plurality of gates for performing a readout on any quantum dot in the two-dimensional array of quantum dots are used to load electrons into the two-dimensional array of quantum dots.

Example 27 includes a quantum compute device comprising the apparatus of any of Examples 20-26, further comprising quantum/classical interface circuitry coupled to the apparatus; and a processor coupled to the quantum/classical interface circuitry.

Example 28 includes an apparatus comprising means for establishing a two-dimensional array of quantum dots in a quantum well of a quantum processor die, wherein the two-dimensional array of quantum dots comprises at least four rows of quantum dots and at least four columns of quantum dots; and means for performing a readout on any quantum dot in the two-dimensional array of quantum dots.

Example 29 includes the subject matter of Example 28, and wherein the means for establishing a two-dimensional array of quantum dots comprises a plurality of rows of plunger gates, wherein at least part of the means for performing a readout extends through two or more rows of the plurality of rows of plunger gates.

Example 30 includes the subject matter of any of Examples 28 and 29, and wherein the means for performing a readout comprises a plurality of single-electron transistors (SETs), wherein individual SETs of the plurality of SETs comprise a first ohmic contact, a first accumulator gate, a first barrier gate, a plunger gate, a second barrier gate, a second accumulator gate, and a second ohmic contact.

Example 31 includes the subject matter of any of Examples 28-30, and wherein the first accumulator gate of individual SETs of at least some of the plurality of SETs is shared with an adjacent SET, wherein the second accumulator gate of individual SETs of at least some of the plurality of SETs is shared with an adjacent SET.

Example 32 includes the subject matter of any of Examples 28-31, and wherein the first accumulator gate of individual SETs of the plurality of SETs is dedicated to the individual SETs, wherein the second accumulator gate of individual SETs of the plurality of SETs is dedicated to the individual SETs.

Example 33 includes the subject matter of any of Examples 28-32, and wherein, from a top-down perspective, a ratio of a width to a length of individual plunger gates of the means for establishing a two-dimensional array of quantum dots is between 0.8 and 1.2.

Example 34 includes the subject matter of any of Examples 28-33, and wherein, in use, one or more components of individual SETs of the means for performing a readout on any quantum dot in the two-dimensional array of quantum dots are used to load electrons into the two-dimensional array of quantum dots.

Example 35 includes a quantum compute device comprising the apparatus of any of Examples 28-34, further comprising quantum/classical interface circuitry coupled to the apparatus; and a processor coupled to the quantum/classical interface circuitry.

1. An apparatus comprising:
a quantum well layer defined in a quantum processor die;
a two-dimensional array of plunger gates to establish a two-dimensional array of quantum dots in the quantum well layer, wherein the two-dimensional array of plunger gates is defined by an upper boundary and a lower boundary;
a first linear array of single-electron transistors (SETS), wherein the first linear array of SETs is disposed along the upper boundary; and
a second linear array of single-electron transistors (SETS), wherein the second linear array of SETs is disposed along the lower boundary.

2. The apparatus of claim 1, wherein the two-dimensional array of plunger gates comprises four rows of plunger gates.

3. The apparatus of claim 1, wherein the two-dimensional array of plunger gates comprises a plurality of rows of plunger gates,
wherein individual SETs of the two-dimensional array of the SETs are sensitive to a plurality of qubits corresponding to two or more rows of the plurality of rows of plunger gates.

4. The apparatus of claim 1, wherein individual SETs of the first linear array of SETs and second linear array of SETs comprise a first ohmic contact, a first accumulator gate, a first barrier gate, a plunger gate, a second barrier gate, a second accumulator gate, and a second ohmic contact.

5. The apparatus of claim 4, wherein the first accumulator gate of individual SETs of at least some of the first linear array of SETs and the second linear array of SETs is shared with an adjacent SET, wherein the second accumulator gate of individual SETs of at least some of the first linear array of SETs and the second linear array of SETs is shared with an adjacent SET.

6. The apparatus of claim 4, wherein the first accumulator gate of individual SETs of the first linear array of SETs and the second linear array of SETs is dedicated to the individual SETs, wherein the second accumulator gate of individual SETs of the first linear array of SETs and the second linear array of SETs is dedicated to the individual SETs.

7. The apparatus of claim 1, wherein, from a top-down perspective, a ratio of a width to a length of individual plunger gates of the two-dimensional array of plunger gates is between 0.8 and 1.2.

8. The apparatus of claim 1, wherein, in use, one or more components of individual SETs of the first linear array of SETs and the second linear array of SETs are used to load electrons into the two-dimensional array of quantum dots.

9. The apparatus of claim 1, wherein individual quantum dots of the two-dimensional array of quantum dots are coupled to every other quantum dot of the two-dimensional array of quantum dots by zero or more intermediate quantum dots of the two-dimensional array of quantum dots.

10. The apparatus of claim 1, further comprising:
quantum/classical interface circuitry coupled to the two-dimensional array of plunger gates; and
a processor coupled to the quantum/classical interface circuitry.

11. An apparatus comprising:
a stack comprising a plurality of semiconductor layers, the plurality of semiconductor layers defining a quantum well in the stack;
a two-dimensional array of plunger gates to establish a two-dimensional array of quantum dots in the quantum well;
a first single-electron transistor (SET), wherein, from a top-down perspective, individual quantum dots of the two-dimensional array of quantum dots are below the first SET; and
a second single-electron transistor (SET), wherein, from the top-down perspective, individual quantum dots of the two-dimensional array of quantum dots are above the second SET.

12. The apparatus of claim 11, wherein the two-dimensional array of plunger gates comprises four rows of plunger gates.

13. The apparatus of claim 11, wherein the first SET comprises a first ohmic contact, a first accumulator gate, a first barrier gate, a plunger gate, a second barrier gate, a second accumulator gate, and a second ohmic contact.

14. The apparatus of claim 13, wherein the first accumulator gate is shared with an adjacent SET, wherein the second accumulator gate is shared with an adjacent SET.

15. The apparatus of claim 13, wherein the first accumulator gate of the first SET is dedicated to the first SET, wherein the second accumulator gate of the first SET is dedicated to the first SET. 16 The apparatus of claim 11, wherein, from a top-down perspective, a ratio of a width to a length of individual plunger gates of the two-dimensional array of plunger gates is between 0.8 and 1.2.

17. The apparatus of claim 11, wherein, in use, one or more components of the first SET and the second SET are used to load electrons into the two-dimensional array of quantum dots.

18. The apparatus of claim 11, wherein individual quantum dots of the two-dimensional array of quantum dots are coupled to every other quantum dot of the two-dimensional array of quantum dots by zero or more intermediate quantum dots of the two-dimensional array of quantum dots.

19. An apparatus comprising:
a plurality of gates for establishing a two-dimensional array of quantum dots in a quantum well of a quantum processor die, wherein the two-dimensional array of quantum dots comprises at least four rows of quantum dots and at least four columns of quantum dots; and
a plurality of gates for performing a readout on any quantum dot in the two-dimensional array of quantum dots.

20. The apparatus of claim 19, wherein the plurality of gates for establishing a two-dimensional array of quantum dots comprises a plurality of rows of plunger gates,
wherein the plurality of gates for performing a readout are able to perform a readout on quantum dots in two or more rows of the plurality of rows of plunger gates.
